(19) United States
(12) Patent Application Publication
(10) Pub. No.: US 2009/0045552 A1
(43) Pub. Date: Feb. 19, 2009

(54) Positive resist composition for recording medium master, and method of producing recording medium master and method of producing stamper using the same

(76) Inventors: Genji Imai, Kanagawa (JP); Daisuke Kojima, Kanagawa (JP)

Correspondence Address: FITCH, EVEN, TABIN & FLANNERY, P. O. BOX 18415, WASHINGTON, DC, 20036, US

(21) Appl. No.: 11/918,739

(22) PCT Filed: Apr. 18, 2006
(86) PCT No.: PCT/JP2006/308115

§ 371 Date: Oct. 18, 2007

(30) Foreign Application Priority Data
Apr. 20, 2005 (JP) 2005-122731

(51) Int. Cl. H05B 6/02; G03C 1/73; G03F 7/20

(52) U.S. Cl. 264/488; 430/286.1; 430/285.1; 430/321; 430/320

(57) ABSTRACT

Provided are a positive resist composition for recording medium master showing excellent plating resistance and adhesion to a base plate such as glass or the like characterized by containing a vinyl polymer which has a monomer unit having an alkali-soluble group blocked by an alkyl vinyl ether, and a method of producing a recording medium master or stamper using this positive resist composition.

### TECHNICAL FIELD

The present invention relates to a positive resist composition useful for a master for producing a recording medium such as optical disks, a method of producing a recording medium master using this positive resist composition, and a method of producing a stamper for recording medium using this positive resist composition.

### BACKGROUND ART

Recently, for increasing capacities of recording media such as optical disks, there are suggested various technologies for producing a recording medium of high density. On the other hand, as general methods for producing an optical disk, there are methods in which, first, a master is produced having a desired pattern according to information signals formed on its surface, a stamper is produced from this master, and using this stamper or using a stamper further produced using this stamper as a master, an optical disk is produced in large amount by injection molding and the like.

Specifically, for example, a photoresist is applied on a glass base plate, irradiation with a laser light is performed according to information signals, and a resist film after exposure is developed to form a pattern of pit, track and the like, to obtain a desired master. On the surface of this master, an electrically conductive film made of nickel and the like is formed by a method such as sputtering, further, nickel is electroformed on the electrically conductive film and this is peeled from the master, thereby, a master stamper can be obtained (see, e.g., Japanese Patent Application Laid-Open (JP-A) Nos. 2002-150620 and 2001-338444). Particularly in patent document 1, a positive resist composition containing a compound generating an acid by exposure is used. However, these conventional technologies are still required to be improved in aspects of resolution limit of recording pit size based on diffraction limit depending on recording light wavelength, adhesion of a pattern (pit) resulted from a resist composition to a base plate such as a glass plate, durability in various treatments for forming an electrically conductive film on this pattern, and the like.

### DISCLOSURE OF INVENTION

An object of the present invention is to provide a positive resist composition used for producing a master and stamper for producing a recording medium such as optical disks, the composition showing excellent adhesion to a base plate and excellent durability in forming an electrically conductive film.

The positive resist composition for recording medium master of the present invention is comprising a vinyl polymer which has a monomer unit having an alkali-soluble group blocked by an alkyl vinyl ether.

The method of producing a recording medium master of the present invention is comprising:

a step of forming a layer of a positive resist composition on a base plate,

a step of irradiating a given portion of the layer with an active energy ray, and

a step of removing the irradiated portion from said base plate by alkali development to form a pattern of said positive resist composition according to information signals on the base plate,

wherein said positive resist composition contains a vinyl polymer which has a monomer unit having an alkali-soluble group blocked by an alkyl vinyl ether.

The method of producing a stamper for recording medium of the present invention is comprising:

a step of forming a layer of a positive resist composition on a base plate,

a step of irradiating a given portion of the layer with an active energy ray,

a step of removing the irradiated portion from said base plate by alkali development to form a pattern of said positive resist composition according to information signals on the base plate thereby obtaining a master,

a step of forming an electrically conductive film on the surface of the master, a process of electroforming a metal on the electrically conductive film and

a step of peeling from the master a stamper made of the metal after electroformation,

wherein said positive resist composition contains a vinyl polymer which has a monomer unit having an alkali-soluble group blocked by an alkyl vinyl ether.

The positive resist composition of the present invention shows excellent plating resistance and adhesion to a base plate such as glass, and is very useful for application of masters for producing a recording medium such as optical disks.

Further, the method of producing a recording medium master and the method of producing a stamper for recording medium of the present invention are capable of forming a pit of small diameter without using electron beam and the like and very useful as a nano processing method of high productivity, in addition to having the above-described effect.

Furthermore, if the positive resist composition of the present invention contains a photothermal converting substance [component (B)] generating heat by an active energy ray and a thermal acid generator [component (C)] generating an acid by heat, in addition to a vinyl polymer [component (A)] which has a monomer unit having an alkali-soluble group blocked by an alkyl vinyl ether, desired sensitivity and resolution are obtained, and by selecting the formulation, a positive resist composition of which baking treatment conditions can be reduced or of which baking treatment can be omitted is preferably obtained.

### BRIEF DESCRIPTION OF DRAWING

FIG. 1 shows schematic sectional views exemplifying a process of producing a master for optical disk (recording medium) and a stamper using a positive resist composition of the present invention.

### BEST MODE FOR CARRYING OUT THE INVENTION

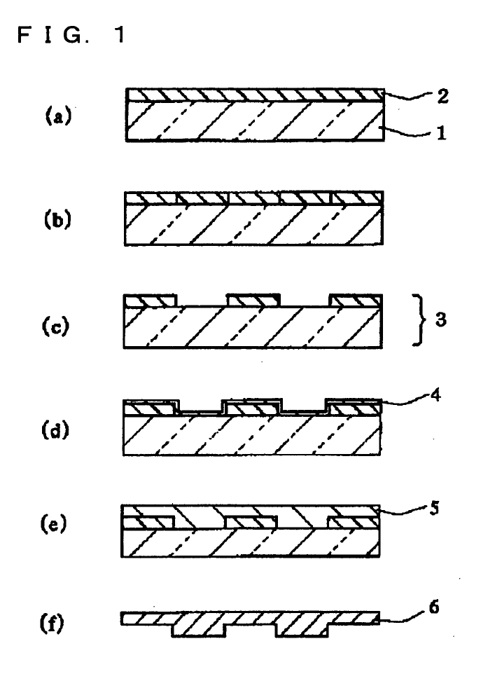

FIG. 1 shows schematic sectional views showing one example of a process of producing a master for optical disk (recording medium) and a stamper using a positive resist composition of the present invention.

First, as shown in FIG. 1(a), a positive resist composition of the present invention is applied on the surface of a base plate 1 of which surface has been polished, to form a resist film 2. Here, as the base plate 1, a glass plate is generally used, and in particular, a glass plate which has been treated with silazane previously is preferably used. Also, metal plates and the like can be used in addition to glass plates. Specific examples of the usable metal base plate include metal places made of Al, Cu, Ni, Ti and the like, and base plates obtained by forming on a suitable base body such as a glass plate, a thin film of a metal such as Al, Au, Ag, Ni and Pt or an inorganic compound such as ITO, ZnO, SiO₂, SnO₂ and SiC by vapor deposition, sputtering and the like.

Further, as the method of applying a positive resist composition on the surface of a base plate 1 to form a resist film 2, there is generally used a method in which a positive resist composition is dissolved in a solvent, and the resist solution is applied by a method such as spin coat. Here, the resist film formation method is not limited to this, and it is also possible, for example, that a positive resist composition is made into a dry film which is provided on the surface of a base plate 1, or a positive resist composition is made into an aqueous emulsion which is applied on the surface of a base plate 1.

Next, as shown in FIG. 1(b), the resist film 2 is irradiated with a laser light which is an active energy ray in the form of a desired pattern according to information signals to be recorded, to form a latent image. Here, the exposure wavelength is not particularly restricted, and it may be advantageous to effect exposure with an active energy ray of wavelength which causes an action of modification so that the irradiated portion (exposed portion) of the resist film with an active energy ray can be removed by alkali development.

The active energy ray can be selected, for example, from ultraviolet ray, visible ray, near infrared ray, infrared ray and far infrared ray. When a photothermal converting substance for inducing generation of an acid by heat is contained in a positive resist composition, it is possible to use an active energy ray containing any wavelength selected from the maximum absorption wavelength (λmax)±10 nm of the photothermal converting substance, 1/n wavelength thereof (λmax/n) and n-fold wavelength thereof (n·λmax) or a combination of two or more of them. Further, it is preferable that this maximum absorption wavelength is in the range of 200 to 900 nm.

As the laser light irradiation apparatus, apparatuses of both a pulse mode and a continuous irradiation mode can be used.

Then, as shown in FIG. 1(c), the exposed portion of the resist film 2 is removed from the base plate, thereby, a desired irregular pattern such as pit and track is formed to obtain a master 3. A baking treatment by heat may be carried out at least before or after exposure of the resist film 2 (prebake and/or post bake), if necessary.

Then, as shown in FIG. 1(d), an electrically conductive film 4 made of nickel and the like is formed on the surface of the master 3 by a method such as sputtering. Then, as shown in FIG. 1(e), nickel 5 is deposited by electroformation up to desired thickness on the electrically conductive film. Then, as shown in FIG. 1(f), nickel after electroformation is peeled from the master 9, and for example, the rear surface is polished and the inner and outer peripheries are trimmed, obtaining a stamper 6. On thus obtained stamper 6, a desired irregular pattern according to information signals is formed. For formation of the electrically conductive film 4, methods such as electroless plating (chemical plating) can also be utilized.

This stamper is used as a mold for injection molding of a recording medium. By this, a recording medium having a desired irregular pattern (pit) can be produced in large amount. The kind of the recording medium to which the present invention is applied is not particularly restricted. The positive resist composition of the present invention is very useful in that a pit of small diameter can be formed without using electron beam and the like and nano processing of high productivity is possible, in addition to excellent durability in formation of an electrically conductive film onto the surface of a base plate carrying thereon a resist pattern provided and excellent adhesion to the base plate.

The positive resist composition of the present invention contains at least a vinyl polymer which has a monomer unit having an alkali-soluble group blocked by an alkyl vinyl ether. Further, the positive resist composition may further contain at least the following components (B) and (C) in addition to this vinyl polymer as the component (A).

(A) A vinyl polymer which has a monomer unit having an alkali-soluble group blocked by an alkyl vinyl ether.

(B) A photothermal converting substance generating heat by an active energy ray.

(C) A thermal acid generator generating an acid by heat.

The above-described vinyl polymer as the component (A) is a vinyl polymer obtained by using as a monomer at least a compound having a polymerizable ethylenically unsaturated bond, and has a group prepared by blocking an alkali-soluble group using an alkyl vinyl ether which can be detached by an acid, as a unit obtained from a monomer having an ethylenically unsaturated bond.

This compound having an ethylenically unsaturated bond and an alkali-soluble group is not particularly restricted providing it can constitute a structural unit in which an alkali-soluble group can be blocked using an alkyl vinyl ether, further, this block dissociates by the action of an acid, thereby, its portion becomes alkali soluble. Such an alkali-soluble group includes, for example, alkali-soluble groups having a pKa of 11 or less such as a phenolic hydroxyl group, carboxyl group, sulfo group, imide group, sulfoneamide group, N-sulfoneamide group, and N-sulfoneurethane group and active methylene group.

As the structural unit of a vinyl polymer as the component (A), preferable are those containing a moiety of the following formula (1) having a structural unit blocking a carboxyl group.

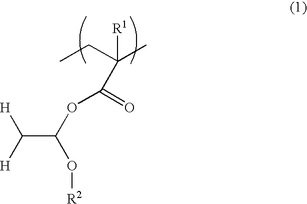

wherein, R¹ represents a hydrogen atom or lower alkyl group, and R² represents a substituted or un-substituted alkyl group.

The lower alkyl group represented by R¹ in the above-described general formula (1) includes, for example, linear or branched alkyl groups having 1 to 8 carbon atoms, and specific examples thereof include a methyl group, ethyl group, propyl group, isopropyl group, butyl group, isobutyl group, sec-butyl group, tert-butyl group, pentyl group, hexyl group, heptyl group, and octyl group.

As the alkyl group represented by R², for example, linear or branched alkyl groups having 1 to 18 carbon atoms are mentioned. Specific examples thereof include a methyl group, ethyl group, propyl group, isopropyl group, butyl group, isobutyl group, sec-butyl group, tert-butyl group, pentyl group, hexyl group, heptyl group, octyl group, nonyl group, decyl group, dodecyl group and octadecyl group, and of them, alkyl groups having 1 to 6 carbon atoms are preferable, further, alkyl groups having 1 to 3 carbon atoms are more preferable.

Examples of the substituent of the substituted alkyl represented by R² include lower alkoxy groups, lower alkanoyl groups, cyano group, nitro group, halogen atoms, and lower alkoxycarbonyl groups.

As portions of the alkyl group of the lower alkyl groups, lower alkoxy groups, lower alkanoyl groups and lower alkoxycarbonyl groups in the above-described definitions of the substituent, the same portions as exemplified for the lower alkyl group represented by R¹ are mentioned. Therefore, examples of the lower alkanoyl group include linear or branched groups having 2 to 9 carbon atoms, and specific examples thereof include an acetyl group, propionyl group, butyryl group, isobutyryl group, valeryl group, isovaleryl group, pivaloyl group, hexanoyl group, and heptanoyl group. The halogen atom includes atoms of fluorine, chlorine, bromine and iodine.

With respect to the monomer for forming a structural unit of the above-described general formula (1), (meth)acrylic acid or its derivative of the following formula (2):

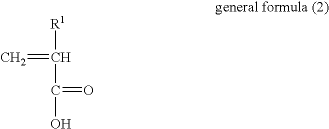

wherein, R¹ is defined as in the above-described general formula (1). and the corresponding alkyl vinyl ether are reacted to block a carboxyl group of the compound of the general formula (2), thereby, a monomer having a structure of the following formula (3) can be obtained:

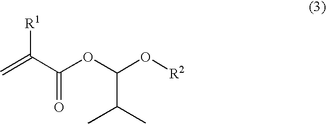

wherein, R¹ and R² are defined as in the general formula (1).

The alkyl vinyl ether to be used in the above-described reaction for forming a monomer may advantageously be that which can block a carboxyl group of a compound having an ethylenically unsaturated bond and an alkali-soluble group such as a carboxyl group constituting units of the monomer, and for example, those having a structure of the following general formula (IV) are preferable.

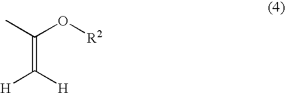

wherein, R² is defined as in the general formula (1)

“Vinyl polymer having a structural unit blocked by an alkyl vinyl ether” to be used as the component (A) can be obtained by performing a polymerization reaction under condition of blocking with an alkyl vinyl ether of an alkali-soluble group of a compound having a polymerizable ethylenically unsaturated bond and an alkali-soluble group as described above. Blocking of an alkali-soluble group with an alkyl vinyl ether can be carried out according to a known method such as a method described in WO 03/6407 pamphlet, and the like.

Further, the vinyl polymer as the component (A) can take a constitution as a copolymer having two or more structural units, and may contain a structural unit obtained from a monomer other than the compound having a polymerizable ethylenically unsaturated bond and an alkali-soluble group, within the range not deteriorating the effect of the present invention. It is not necessary that all alkali-soluble groups of the vinyl polymer are blocked, and 50 mol % or more, preferably 70 mol % or more of monomer units having an alkali-soluble group may be advantageously blocked. Higher the proportion of blocked alkali-soluble groups, further the preservation stability of a polymer itself and a resist composition containing this is improved. Because of inclusion in a polymer of a monomer unit in which an alkali-soluble group is blocked using an alkyl vinyl ether, prebake in forming a photosensitive layer made of a positive resist composition before exposure can be omitted using this polymer. That is, excellent shape stability and close adherence to a base plate can be imparted to a photosensitive layer, even in forming a photosensitive layer at room temperature. Particularly, warping of a base plate in the case of use of a metal and the like as the base plate and an influence of thermal treatment on the quality of a master for stamper (plate precision) based on change in dimension of a base plate due to thermal expansion and constriction in cooling can be excluded.

When a desired property is added by introducing a monomer unit not blocked in the above-described copolymer, the sum of monomer units blocked by an alkyl vinyl ether and monomer units not blocked is preferably 50 to 70%.

As the form of the above-described copolymer, various forms such as a random copolymer, block copolymer and the like can be used.

In the case of use of a monomer of the general formula (3) mentioned above, the content of a monomer of the general formula (3) in raw materials for a vinyl polymer as the component (A) is preferably 2 to 60 wt %, more preferably 5 to 40 wt %. When the content of a monomer of the general formula (3) is 2 wt % or more, the resultant positive resist composition shows more excellent developability, and when 60 wt % or less, a film (coated film) obtained from the composition has a more excellent mechanical property.

As the other monomer which can be used in addition to a compound having an ethylenically unsaturated double bond in which an alkali-soluble group is blocked as the monomer for vinyl polymer formation, compounds having a polymerizable ethylenically unsaturated bond, and the like are mentioned. The proportion of monomer units in which an alkali-soluble group is blocked in the case of such a copolymer based on all monomer units in the copolymer can be preferably 5% or more, more preferably 10% or more.

The compound having a polymerizable ethylenically unsaturated bond is not particularly restricted, and examples thereof include known vinyl monomers such as vinyl acetate, (meth)acrylic acid; alkyl (meth)acrylates composed of an alcohol having 1 to 18 carbon atoms and (meth)acrylic acid such as methyl (meth)acrylate, ethyl (meth)acrylate, butyl (meth)acrylate, isobutyl (meth)acrylate, tert-butyl (meth)acrylate, cyclohexyl (meth)acrylate, 2-ethylhexyl (meth)acrylate, lauryl (meth)acrylate and stearyl (meth)acrylate; aromatic vinyl compounds such as styrene, α-methylstyrene, p-methylstyrene, dimethylstyrene and divinylbenzene; hydroxyalkyl (meth)acrylates such as 2-hydroxyethyl (meth)acrylate and 2-hydroxypropyl (meth)acrylate; glycol di(meth)acrylates such as ethylene glycol di(meth)acrylate and butanediol di(meth)acrylate; alkylaminoalkyl (meth)acrylates such as dimethylaminoethyl (meth)acrylate; fluorine-containing vinyl monomers such as trifluoroethyl (meth)acrylate, pentafluoropropyl (meth)acrylate, perfluorocyclohexyl (meth)acrylate, 2,2,3,3-tetrafluoropropyl (meth)acrylate and β-(perfluorooctyl)ethyl (meth)acrylate; siloxane-containing vinyl monomers such as 1-[3-(meth)acryloxypropyl]-1,1,3,3,3-pentamethyldisiloxane, 3-(meth)acryloxypropyl tris(trimethylsiloxane)silane and AK-5 [silicone macro monomer, manufactured by Toagosei Co., Ltd.]; hydrolysable silyl group-containing vinyl monomers such as vinyltrimethoxysilane, vinyl methyldimethoxysilane, 3-(meth)acryloxypropyltrimethoxysilane, 3-(meth)acryloxypropylmethyldimethoxysilane and 3-(meth)acryloxypropyltriethoxysilane, 3-(meth)acryloxypropyldiethoxysilane; vinyl ethers such as vinyl methyl ether, vinyl ethyl ether and vinyl isobutyl ether; polybasic unsaturated carboxylic acids such as fumaric acid, maleic acid, maleic anhydride, linseed oil fatty acid, tall oil fatty acid and dehydrated castor oil fatty acid, or esters thereof with mono-hydric or poly-hydric alcohols; dimethylaminoethyl (meth)acrylate methyl chloride salt, isobornyl (meth)acrylate, allyl alcohol, allyl alcohol ester, vinyl chloride, vinylidene chloride, trimethylolpropane tri(meth)acrylate, vinyl propionate, (meth)acrylonitrile, macro monomers AS-6, AN-6, M-6, AB-6 [manufactured by Toagosei Co., Ltd.], and the like. These can be selected for use singly or in combination of two or more.

In the present invention, “(meth)acrylic acid” means acrylic acid and methacrylic acid, and other (meth)acrylic acid derivatives also mean the same meanings.

By polymerizing at least one of monomers having a polymerizable unsaturated double bond in which an alkali-soluble group is blocked by at least one of other monomers to be added if necessary, a vinyl polymer which can be used as the component (A) can be obtained. Polymerization can be carried out according to a known method.

In polymerization, a reaction solvent may be used, and the reaction solvent is not particularly restricted providing it is inert to the reaction, and examples thereof include benzene, toluene, xylene, hexane, cyclohexane, ethyl acetate, butyl acetate, methyl lactate, ethyl lactate, dioxane, dioxolane, γ-butyrolactone, 3-methyl-3-methoxybutyl acetate, acetone, methyl ethyl ketone, methyl isobutyl ketone, diisobutyl ketone, cyclohexanone, anisole, methanol, ethanol, propanol, isopropanol, butanol, N-methylpyrrolidone, tetrahydrofuran, acetonitrile, ethylene glycol monobutyl ether, ethylene glycol monobutyl ether acetate, diethylene glycol monobutyl ether, diethylene glycol monobutyl ether acetate, propylene glycol monomethyl ether, dipropylene glycol monomethyl ether, propylene glycol monoethyl ether, propylene glycol monomethyl ether acetate, dipropylene glycol monomethyl ether acetate, methoxybutanol, methoxybutyl acetate, 3-methyl-3-methoxy-1-butanol, water, dimethyl sulfoxide, dimethylformamide and dimethylacetamide.

The polymerization initiator differs depending on polymerization mode, and for example, in radical polymerization, 2,2′-azobisisobutyronitrile (AIBN), 2,2′-azobis-2-methylbutyronitrile (AMBN), 2,2′-azobisvaleronitrile, benzoyl peroxide, acetyl peroxide, lauroyl peroxide, 1,1-bis(t-butyl peroxy)-3,3,5-trimethylcyclohexane, t-butyl peroxy-2-ethyl hexanoate, cumene hydroperoxide, t-butyl peroxybenzoate, t-butyl peroxide, methyl ethyl ketone peroxide, m-chlorobenzoic acid, potassium persulfate, sodium persulfate, ammonium persulfate and the like, and the use amount thereof is preferably 0.01 to 20 wt % based on all raw material.

Examples of the chain transfer agent include thio-β-naphthol, thiophenol, n-butylmercaptane, ethylthioglycolate, mercapto ethanol, isopropyl mercaptan, t-butylmercaptan, diphenyl disulfide, diethyl dithioglycolate, diethyl disulfide and the like, and the use amount thereof is preferably 0.01 to 5 wt % based on all raw material.

The weight average molecular weight of the above-described vinyl polymer is preferably 2,000 to 300,000, more preferably 3,000 to 200,000, further preferably 5,000 to 100,000.

Monomer formulation itself of a vinyl polymer as the component (A), or in combination with the components (B) and (C) to be added if necessary, is so selected as to obtain properties as a positive resist for producing a desired stamper, that is, close adherence with a base plate, patterning precision, durability in forming an electrically conductive film, shape stability of a pattern, and the like. It is preferable to select components (B) and (C) so that desired sensitivity and resolution are obtained at the strength of an active energy ray such as laser light used for exposure. Further, setting is preferably so made that a baking treatment is unnecessary in forming a coat or layer irrespective of wavelength range to be used.

For preparation of a vinyl polymer as the component (A), a method can also be used in which a vinyl polymer having an alkali-soluble group is prepared previously, and this alkali-soluble group is blocked by an alkyl vinyl ether, in addition to a method of preparation by a polymerization reaction using at least a monomer having a polymerizable ethylenical double bond in which an alkali-soluble group has been blocked by an alkyl vinyl ether previously.

The content of a vinyl polymer as the component (A) in a positive resist composition can be selected in the range of preferably 1 to 90 wt %, more preferably 5 to 60 wt %.

When components (B) and (C) are used, the content thereof is preferably 1 to 60 wt %, more preferably 3 to 50 wt % based on the total amount of the components (A), (B) and (C).

The photothermal converting substance to be contained in a positive resist composition if necessary is not particularly restricted providing it is a photothermal converting substance generating heat by an active energy ray and does not deteriorate an application for production of a stamper for producing an optical recording medium or optical magnetic recording medium containing written information by being compounded into a positive resist composition. Such photothermal converting substances include various organic or inorganic dyes and pigments, organic coloring matters, metals, metal oxides, metal carbides, metal borides and the like. Of them, light absorptive coloring matters are useful. As the photothermal converting substance, those showing a maximum absorption wavelength (λmax) in the range of 200 to 900 nm are suitable. Specifically, those absorbing a wavelength of 266 nm, 351 nm, 355 nm, 375 nm, 405 nm, 436 nm, 650 nm, 610 nm, 760 nm or 830 nm to generate heat can be used. For example, when a wavelength of 405 nm is utilized, light absorptive coloring matters absorbing efficiently lights in the wavelength range of 380 to 430 nm (λ1) and the wavelength range of 760 to 860 nm (λ1×n=2) in a positive resist composition can be used.

Specific examples of coloring matters for obtaining heat exchangeability of an active energy ray include various pigments such as carbon black; cyanine coloring matters, phthalocyanine coloring matters, naphthalocyanine coloring matters, merocyanine coloring matters, coumarin coloring matters, azo coloring matters, polymethine coloring matters, squarylium coloring matters, croconium coloring matters, pyrylium coloring matters and thiopyrylium coloring matters. Of them, cyanine coloring matters, coumarin coloring matters and phthalocyanine coloring matters are preferably mentioned. These can be used singly or, if necessary, in combination of two or more. Specific examples of the coloring matters are mentioned below. Wavelengths and solvent names appended to chemical formulae show maximum absorption wavelengths (λmax) and solvents used in measuring the maximum absorption wavelength by an ordinary method.

Specific examples of the cyanine coloring matter include the following compounds.

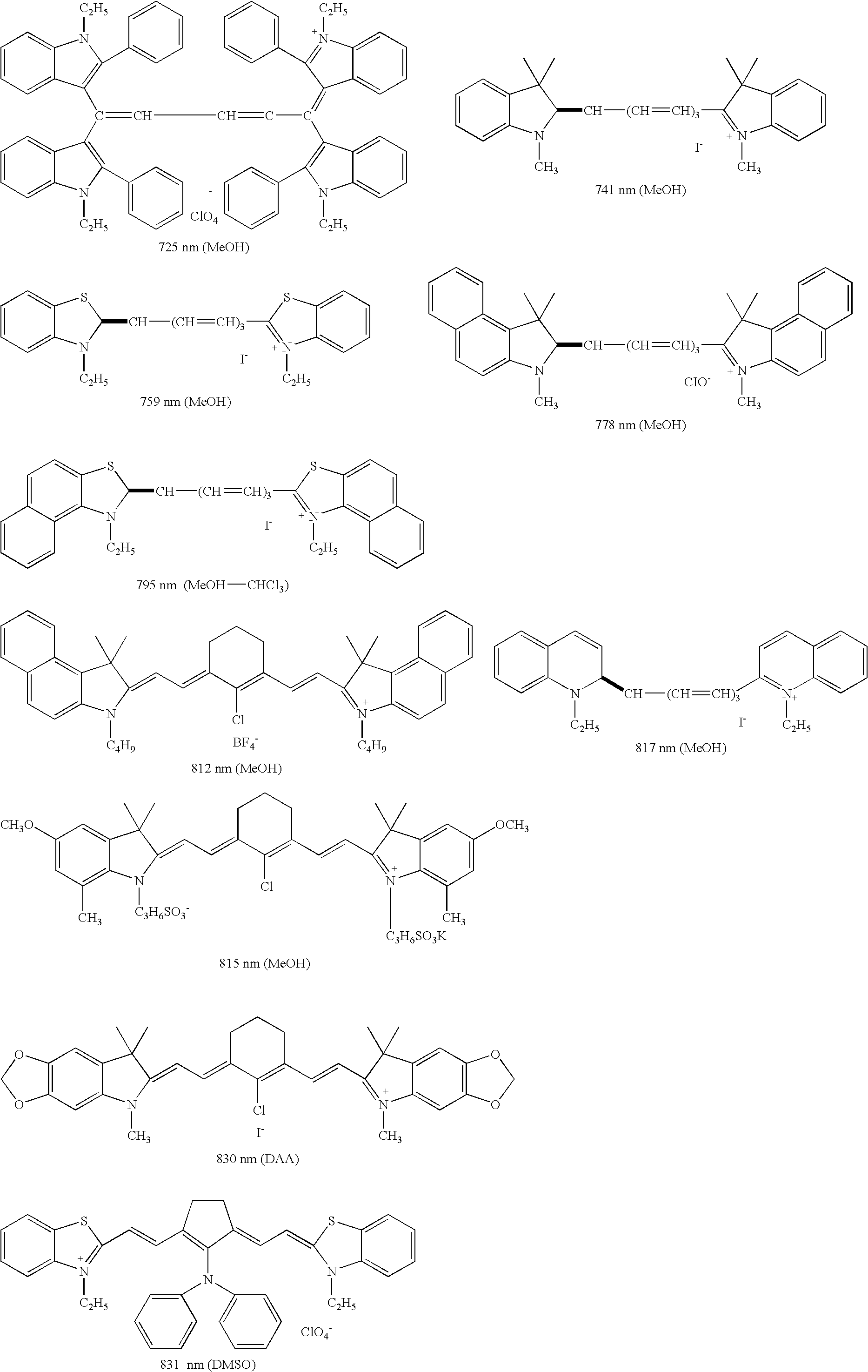

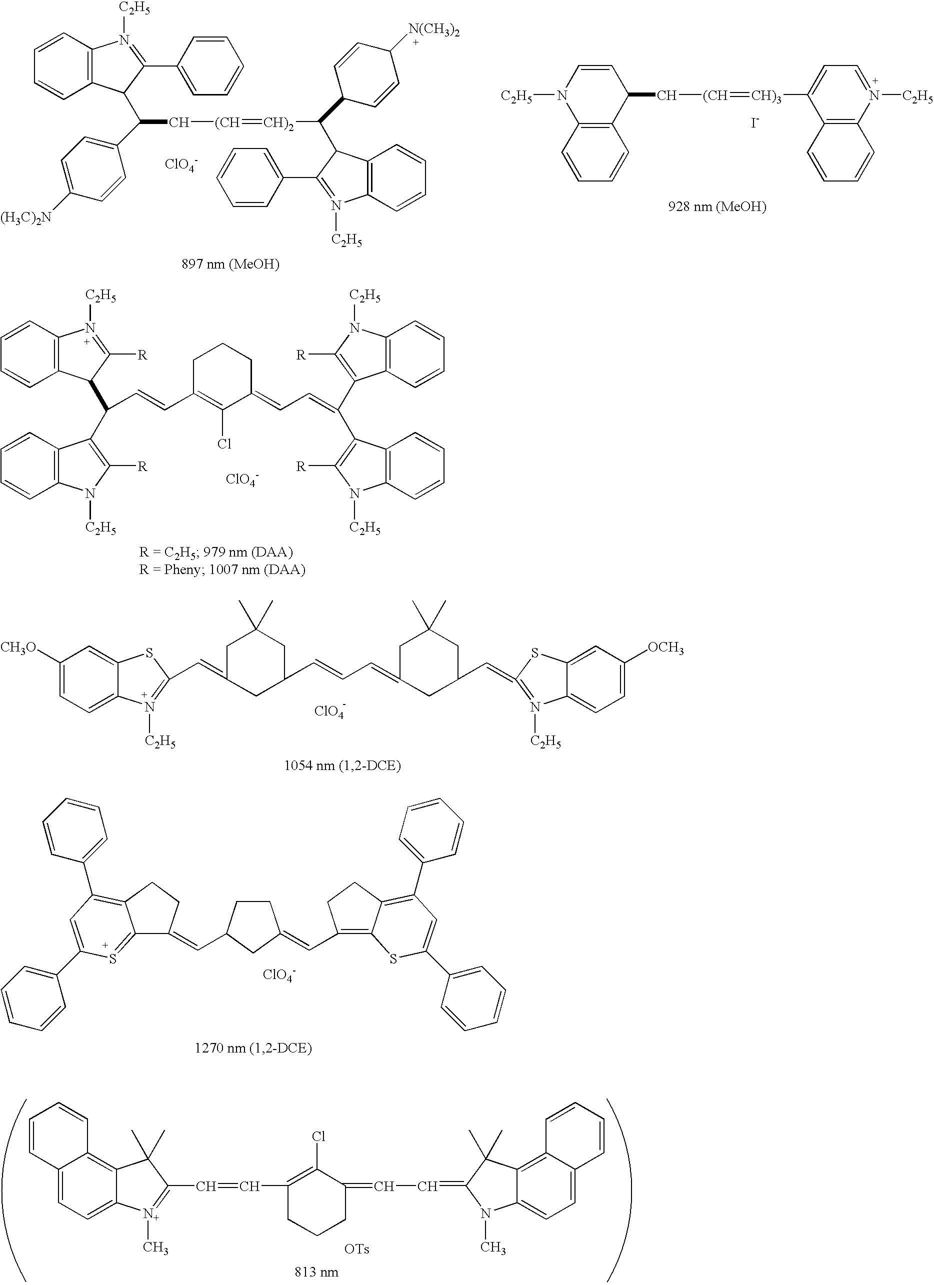

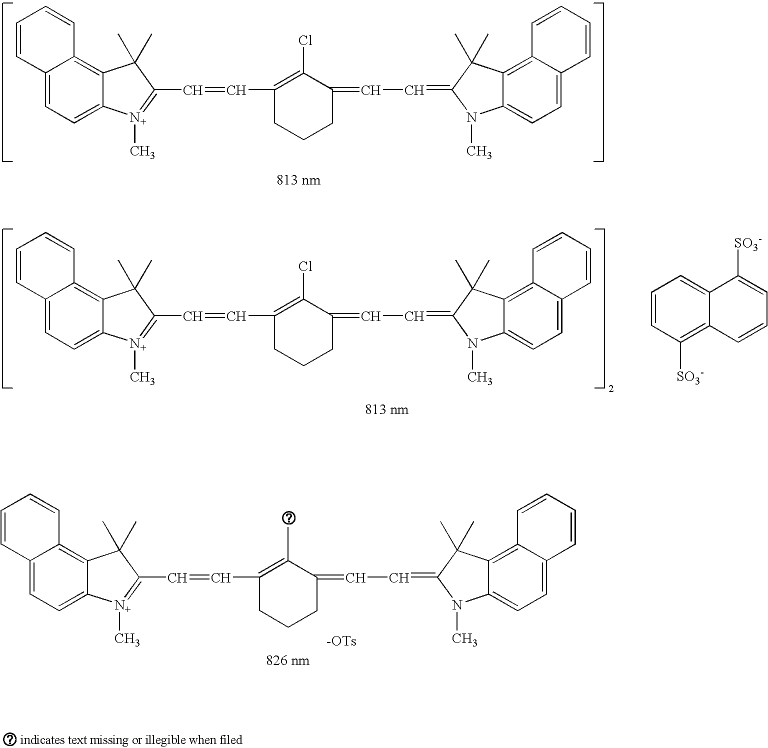

(all of the wavelengths of the above-described 4 coloring matters are values measured in methanol (MeOH)).

Specific examples of the phthalocyanine coloring matter include the following compounds.

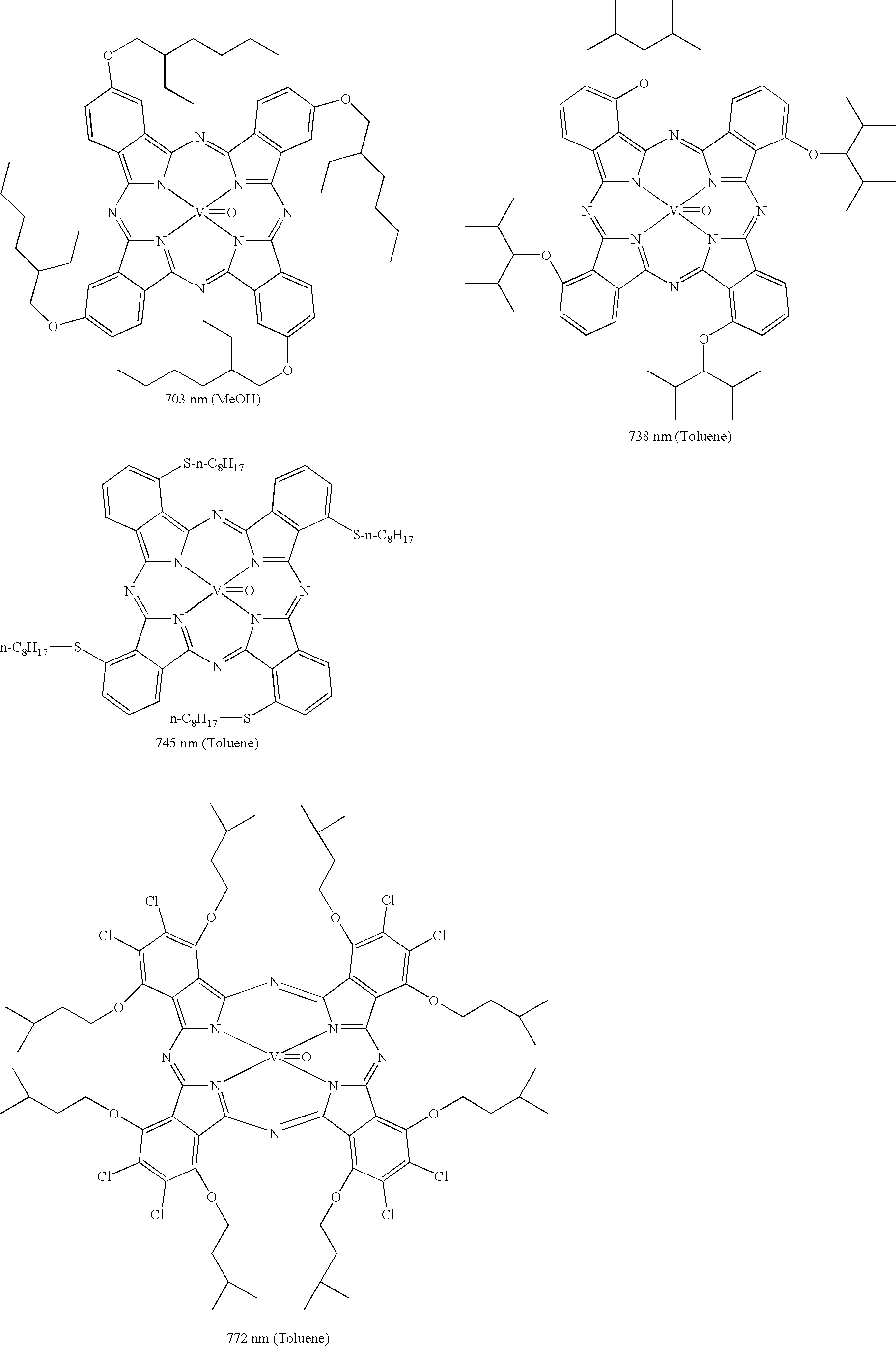

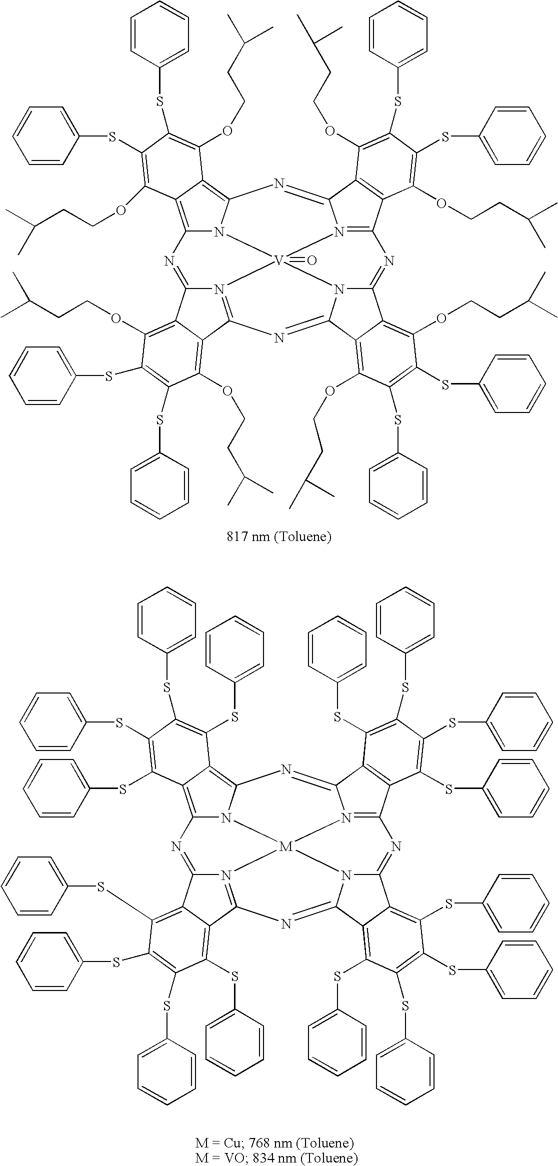

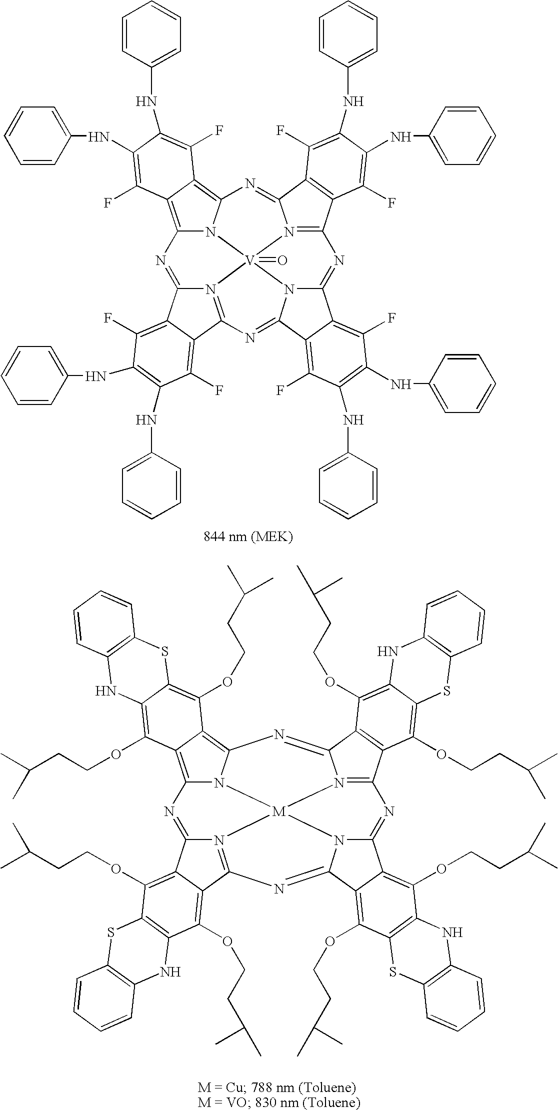

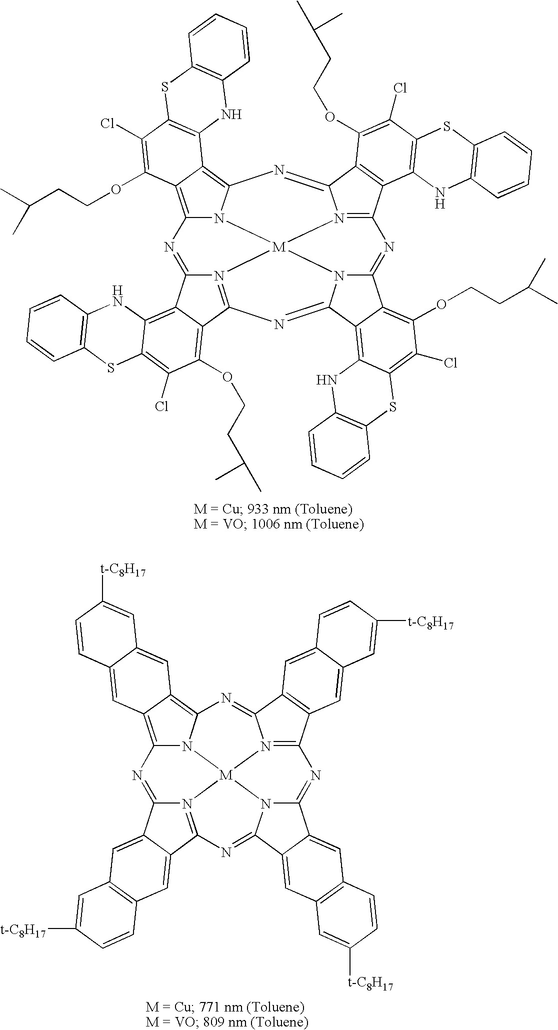

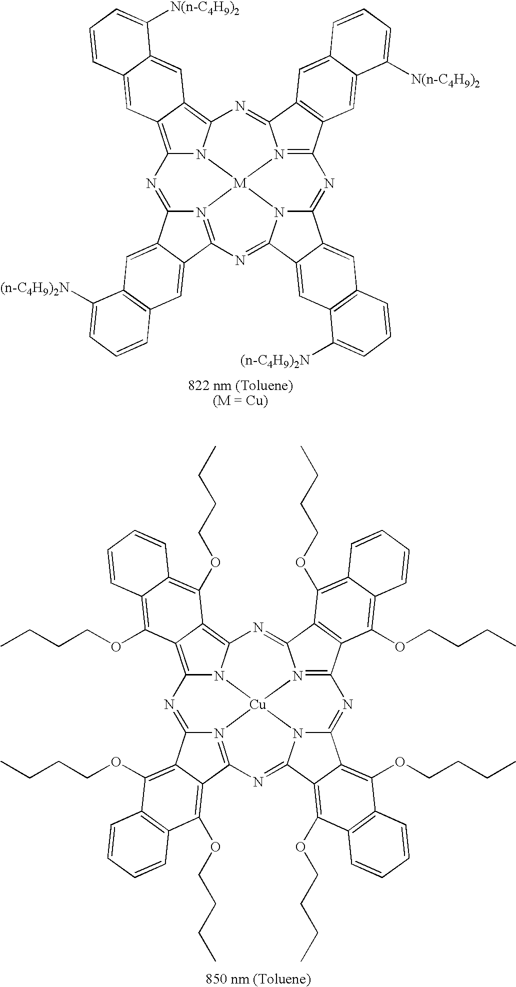

Further, the following dyes are exemplified.

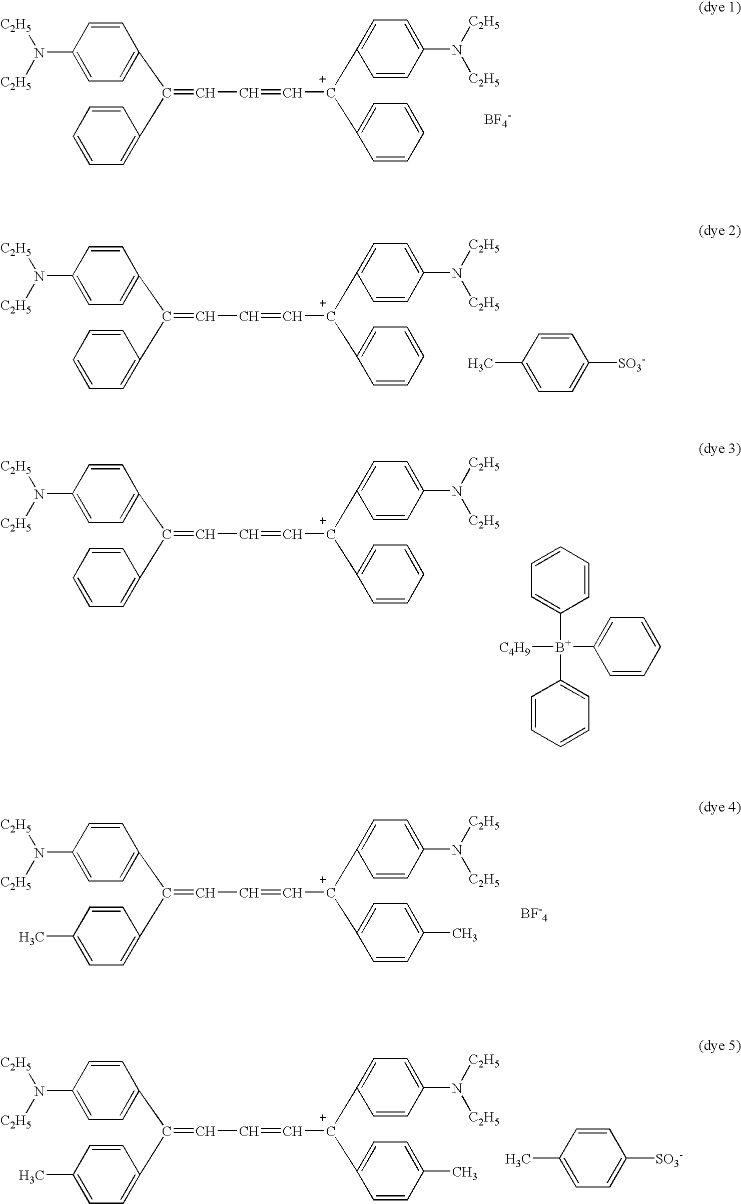

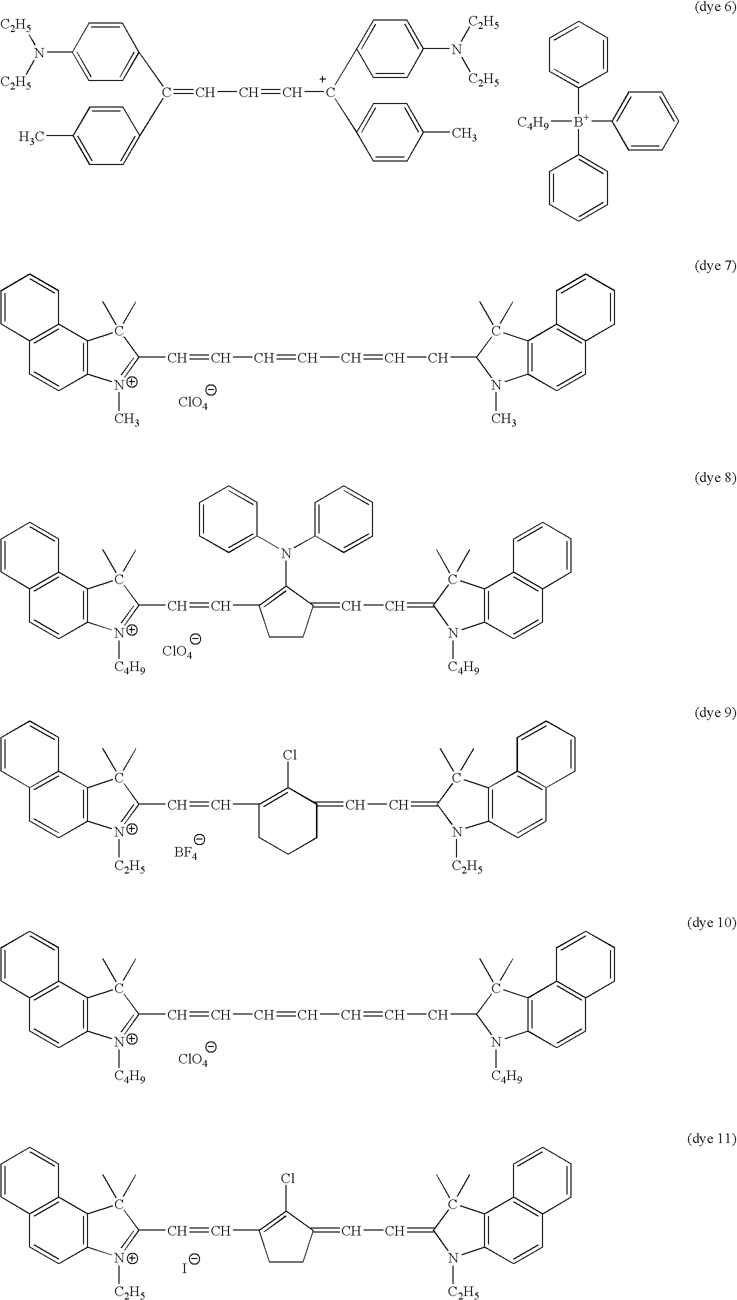

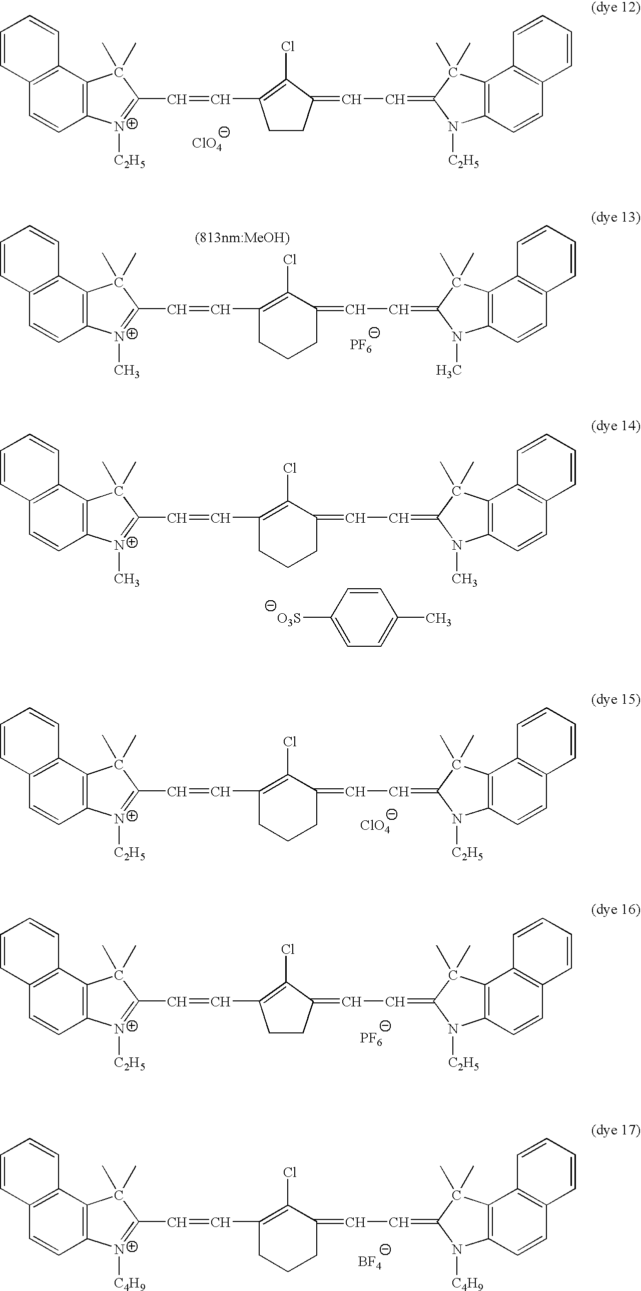

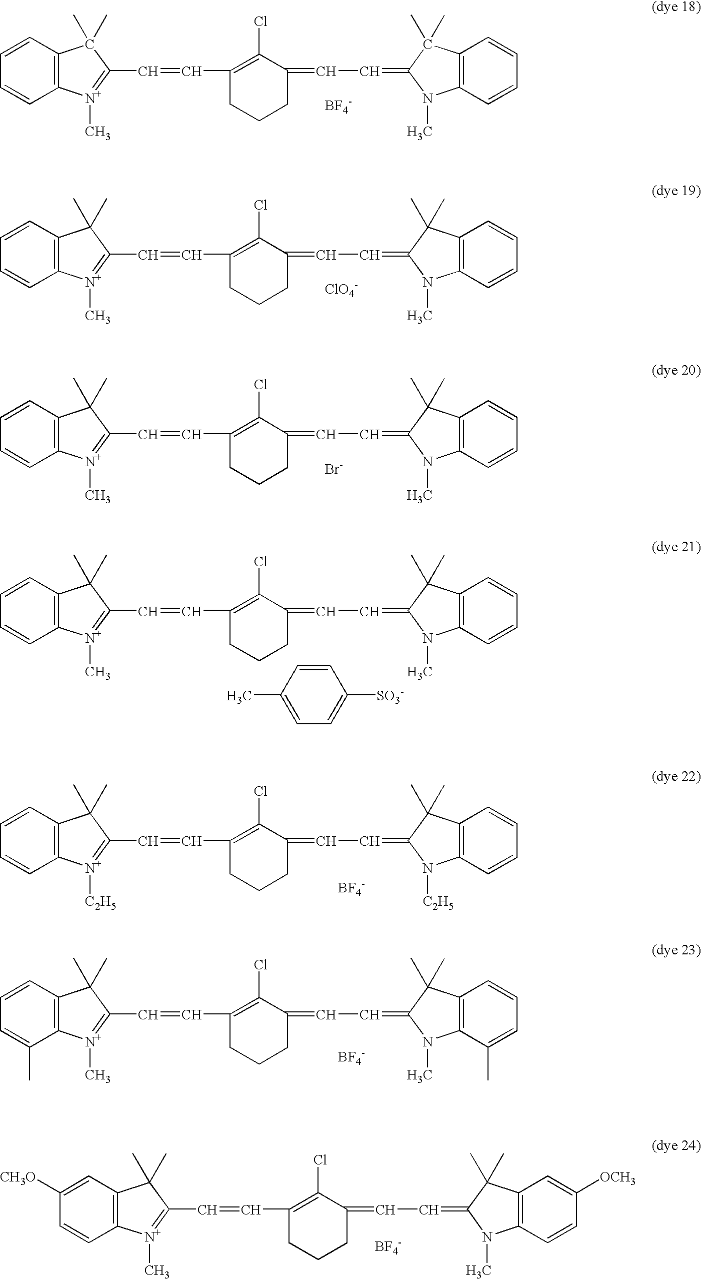

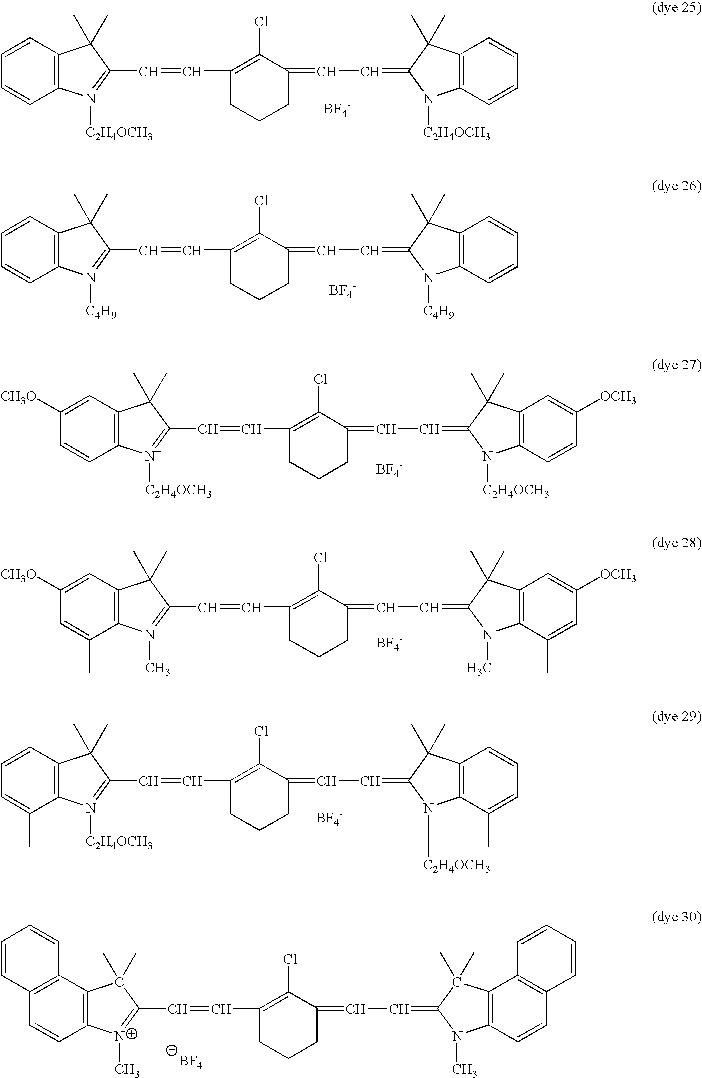

Of them, dye 16 is particularly preferable.

Further, of these dyes, those containing a counter ion ⁻BF₄ are preferable from the standpoint of preservation stability.

Further, the following dyes are exemplified.

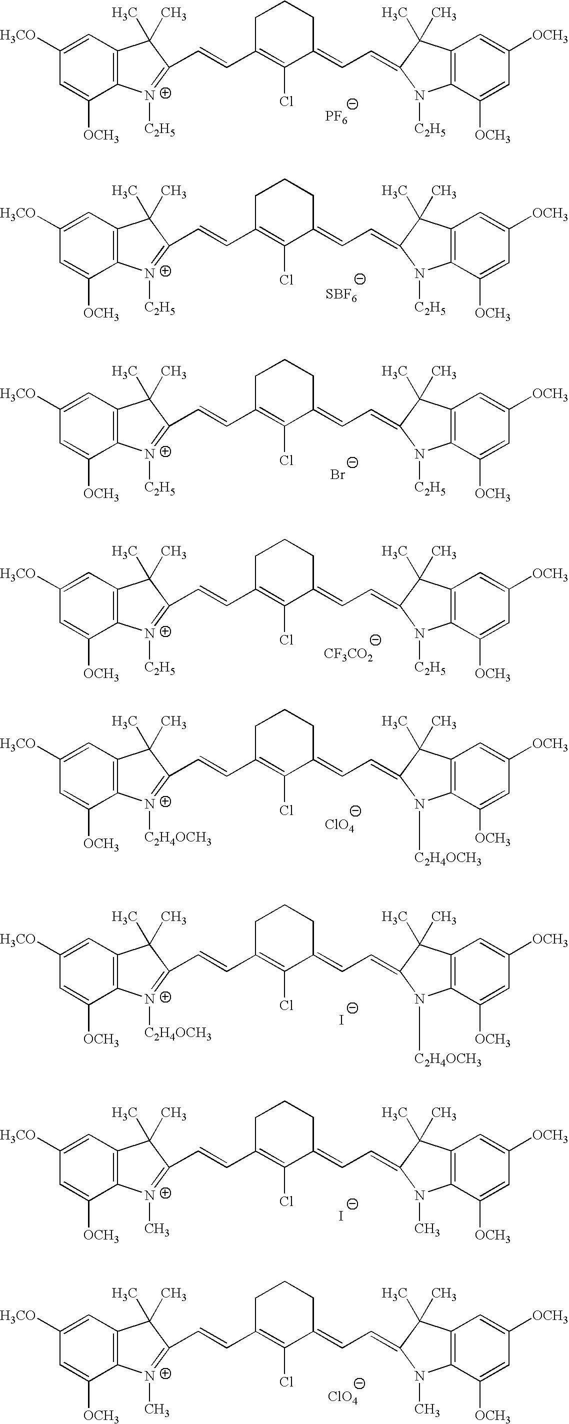

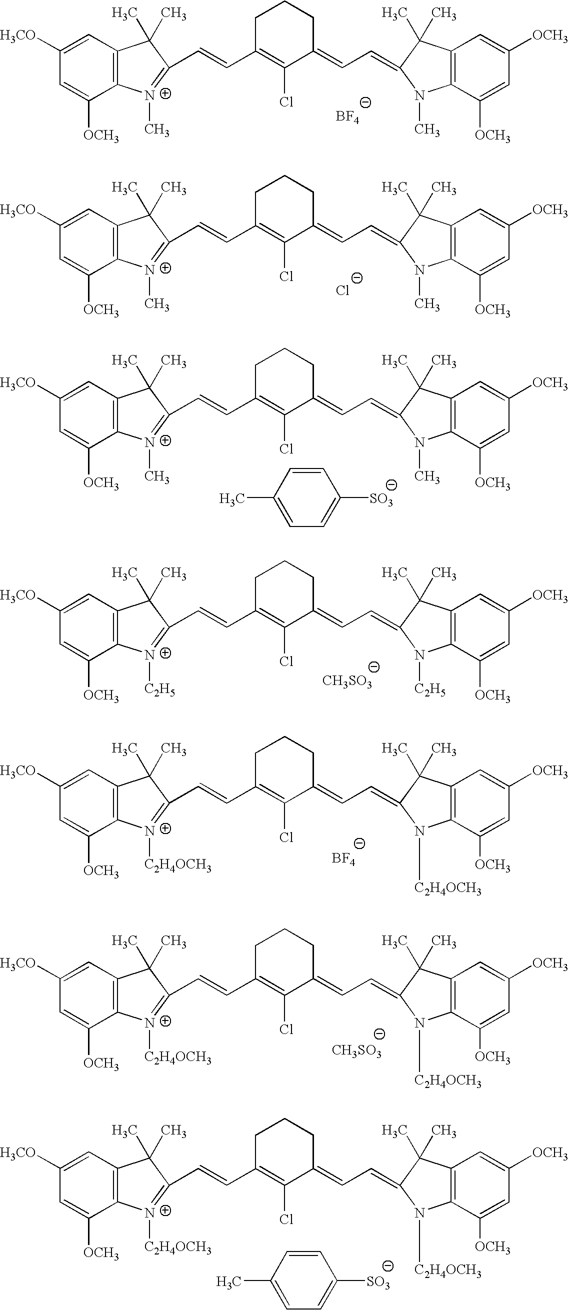

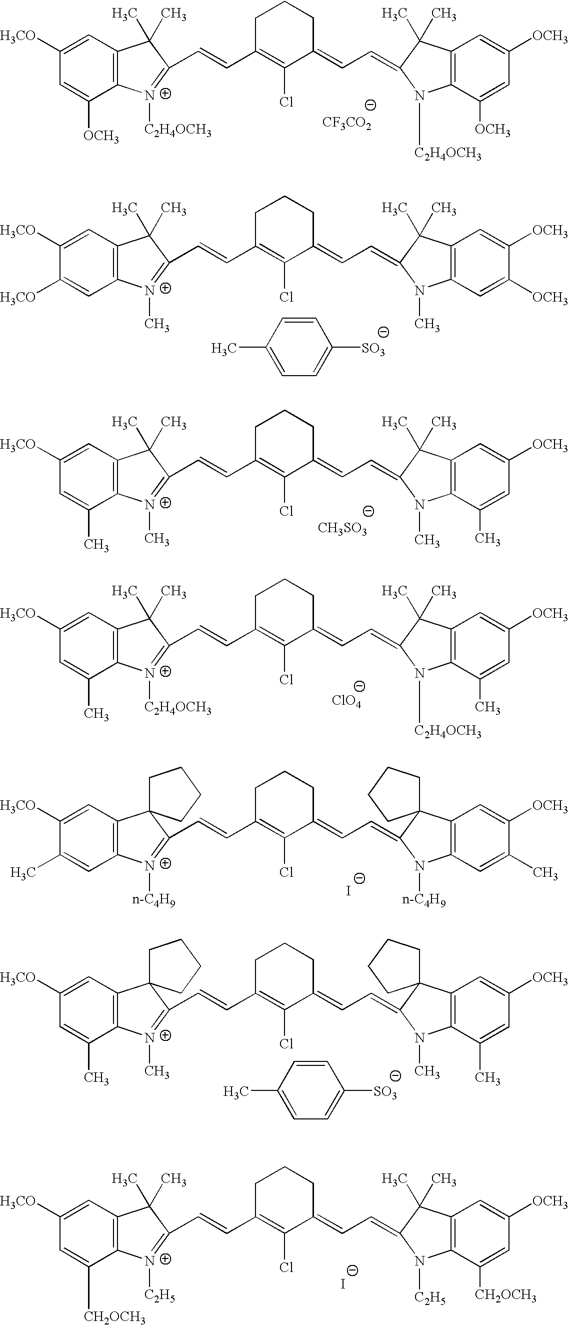

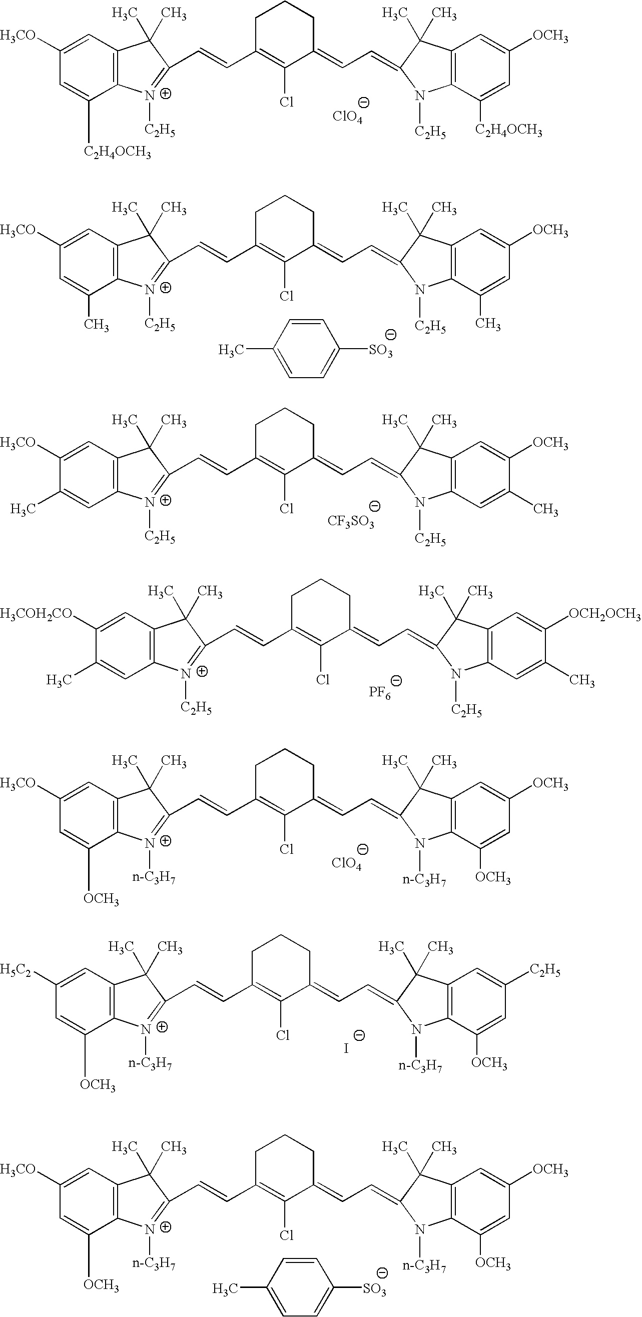

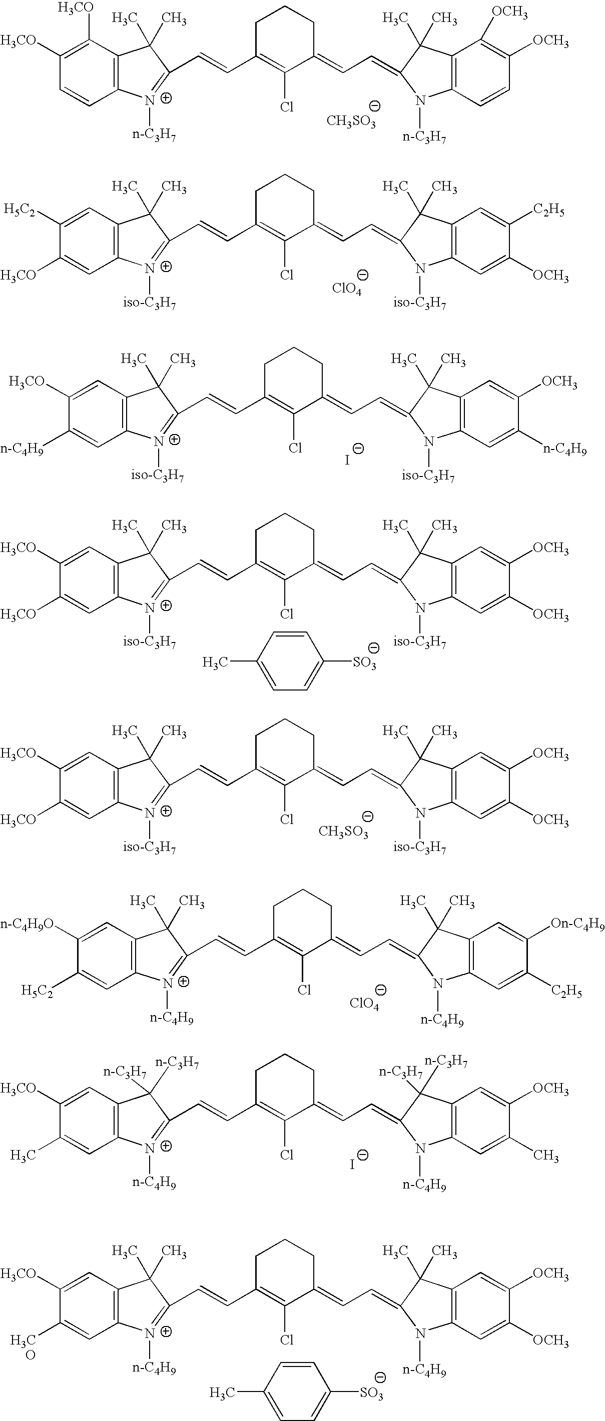

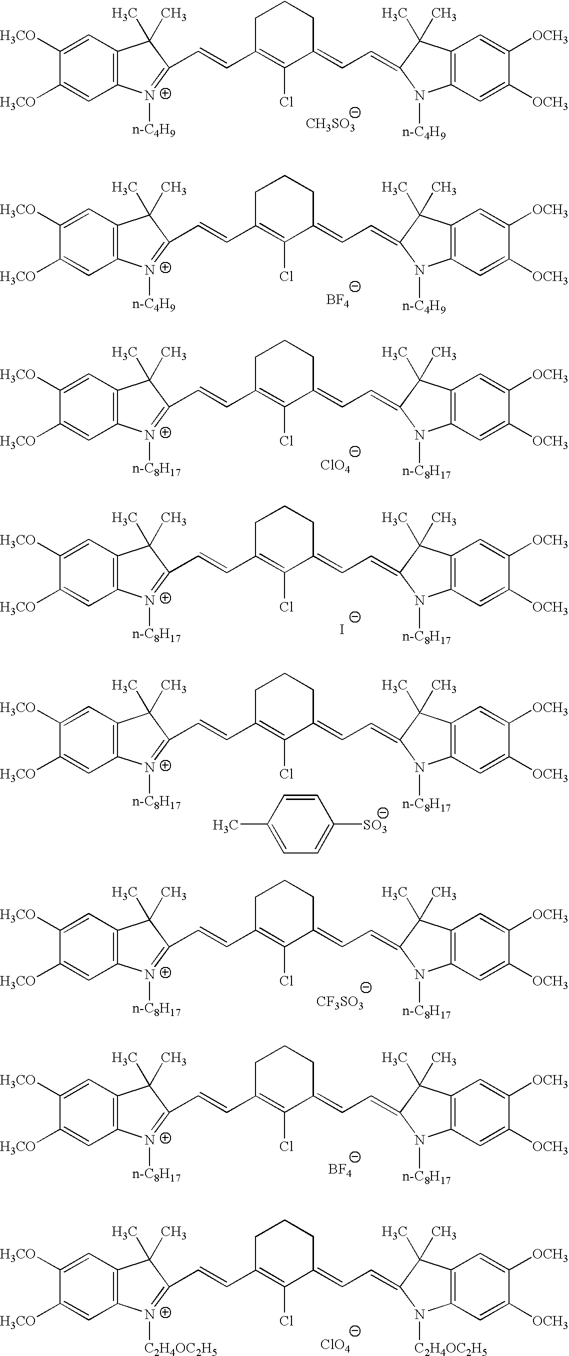

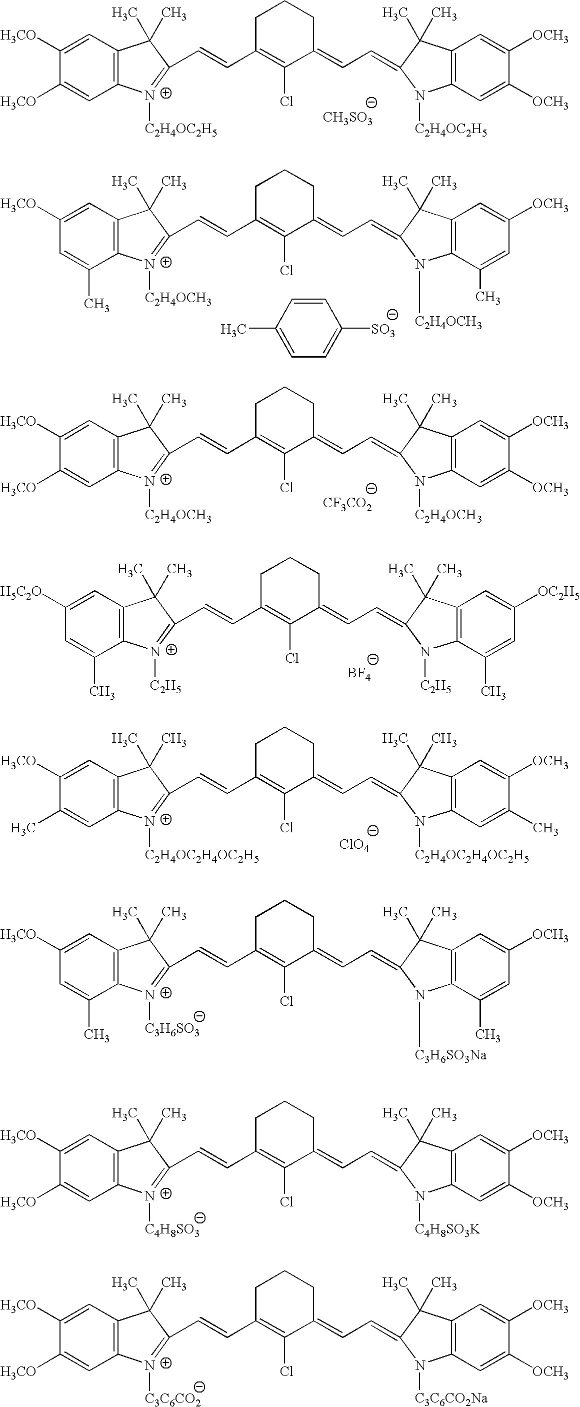

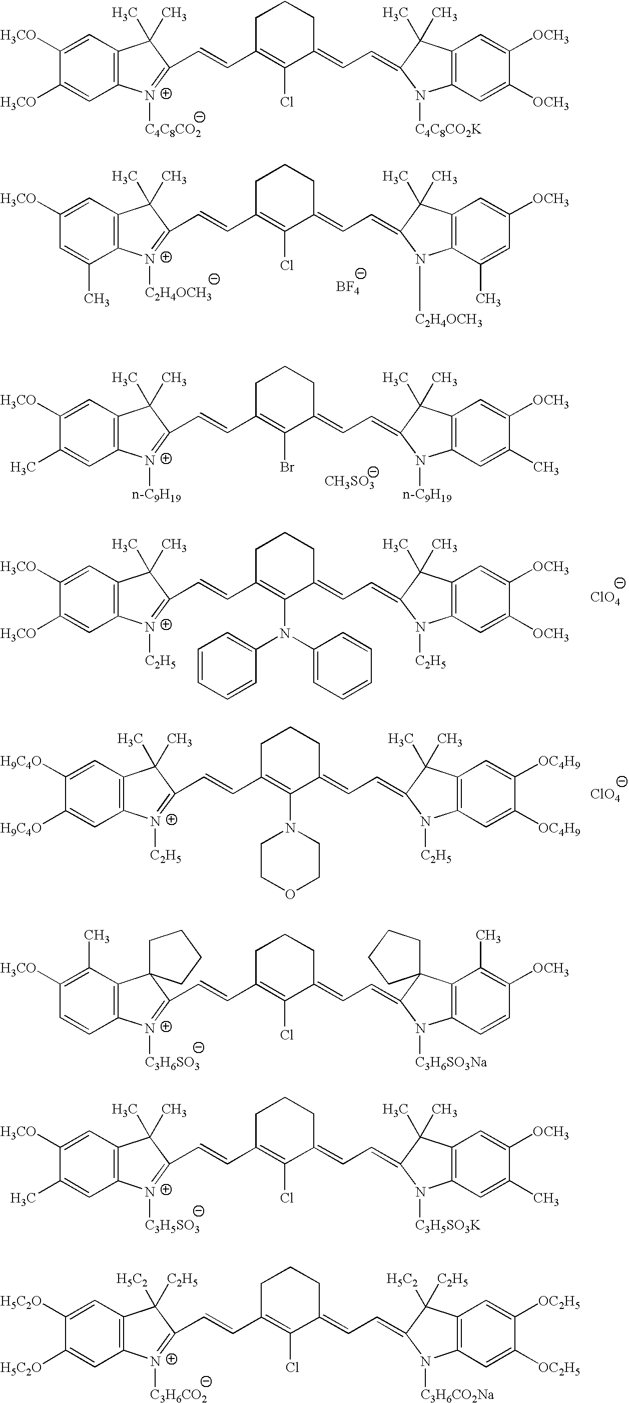

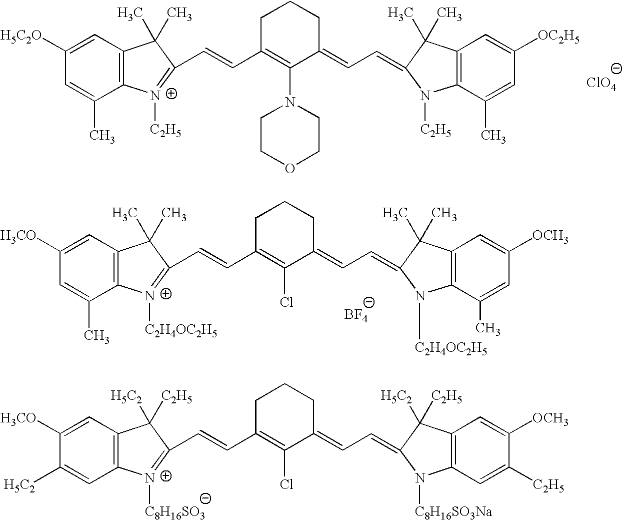

Specific examples of commercially available preferable photothermal converting substances include, but not limited to, “KAYASORB” series: CY-10, CY-17, CY-5, CY-4, CY-2, CY-20 and CY-30 and IRG-002 (these are manufactured by Nippon Kayaku Co., Ltd.); YKR-4010, YKR-3030, YKR-3070, YKR2900, SIR-159, PA-1005, SIR-128, YKR-2080 and PA-1006 (these are manufactured by Yamamoto Chemicals Inc.); “PROJECT” 825LDI, “PROJECT” 830NP, S174963, S174270 (these are manufactured by Avecia Limited); NK-2014, NK-2911, NK-2912, NK4432, NK-4474, NK-4489, NK4680, NK4776, NK-5020, N-5036 and NK-5042, NK-1342, NK-1977, NK-1886, NK-1819, NK-1331, NK-1837, NK-863, NK-3213, NK-88, NK-3989, NK-1204, NK-723, NK-3984, NKX-1316, NKX-1317, NKX-1318, NKX-1320, NKX-1619, NKX-1767, NKX-1768 (these are manufactured by Hayashibara Biochemical Laboratories, Inc.); IR2T, IR3T (these are manufactured by Showa Denko K.K.); “EXCOLOR” 801K, IR-1, IR-2, “TX-EX-801B” and “TX-EX-805K” (these are manufactured by Nippon Shokubai Co., Ltd.); CIR-1080 (manufactured by Japan Carlit Co., Ltd.); IR98011, IR980301, IR980401, IR980402, IR980405, IR980406 and IR980504 (these are manufactured by YAMADA CHEMICAL K. K.) and “EPOLIGHT” V-149, V-129, V-63, 111-184, 111-192, IV-62B, IV-67, VI-19, VI-148 (these are manufactured by EPOLIN, INC.).

The content of a photothermal converting substance in a positive resist composition in the case of use of the photothermal converting substance is preferably 0.5 to 40 wt %, more preferably 1 to 35 wt % based on the total amount of the components (A), (B) and (C).

Also the kind of the photothermal converting substance and its compounding amount themselves or, in combination with the components (A) and (C), are so selected that a desired property as a positive resist is obtained, and so set as to obtain desired sensitivity and resolution at the strength of an active energy ray such as laser light used for exposure. Further, by regulating the formulation of a positive resist composition, it can be determined whether to perform a baking treatment or not in formation (before exposure) of a coat or layer formed from a positive resist composition or after exposure thereof.

The thermal acid generator as the component (C) can act on a vinyl polymer as the component (A), by the action of heat generated from a photothermal converting substance by exposure, to generate an acid which imparts solubility in a developer to this polymer, and for example, those contained as a thermal acid generator in resist compositions and photosensitive compositions such as onium salts such as organic sulfonium salts, benzothiazolium salts, ammonium salts and phosphonium salts can be used. Further, those capable of generating an acid under heat generation of the above-mentioned photothermal converting substance, among optical acid generators contained in various positive resist compositions, can also be used.

Exemplified as such optical acid generators are salts of diazonium, phosphonium, sulfonium or iodinium with an inorganic acid anion such as a fluorine ion, chlorine ion, bromine ion, iodine ion, perchlorate ion, periodate ion, hexafluorostanate ion, phosphate ion, hydroborofluorate ion and tetrafluoroborate ion, or an organic acid anion such as a thiocyanate ion, benzenesulfonate ion, naphthalenesulfonate ion, naphthalenedisulfonate ion, p-toluenesulfonate ion, alkylsulfonate ion, benzenecarboxyalte ion, alkylcarboxylate ion, trihaloalkylcarboxylate ion, alkylsulfate ion, trihaloalkylsulfate ion and nicotinate ion, further, with an organometal complex anion such as azo, bisphenyldithiol, thiocatechol chelate, thiobisphenolate chelate and bisdiol-α-diketone anions; organic halogen compound; orthoquinone-diazide sulfonyl chloride; oxazole derivatives; triazine derivatives; disulfone derivatives; sulfonate derivatives; diazosulfone derivatives; aromatic sulfone derivatives; organometals; and organic halogen compounds.

As the oxazole derivatives and triazine derivatives, preferably mentioned are oxazole derivatives of the following general formula (PAG1) and s-triazine derivatives of the following general formula (PAG2) containing a substituted trihalomethyl group.

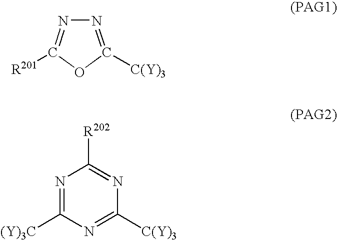

In the formulae, R²⁰¹ represents a substituted or unsubstituted aryl group or alkenyl group, and R²⁰² represents a substituted or unsubstituted aryl group, alkenyl group, alkyl group or —C(Y)₃. Y represents a chlorine atom or bromine atom. Specific examples thereof include, but not limited to, the following compounds.

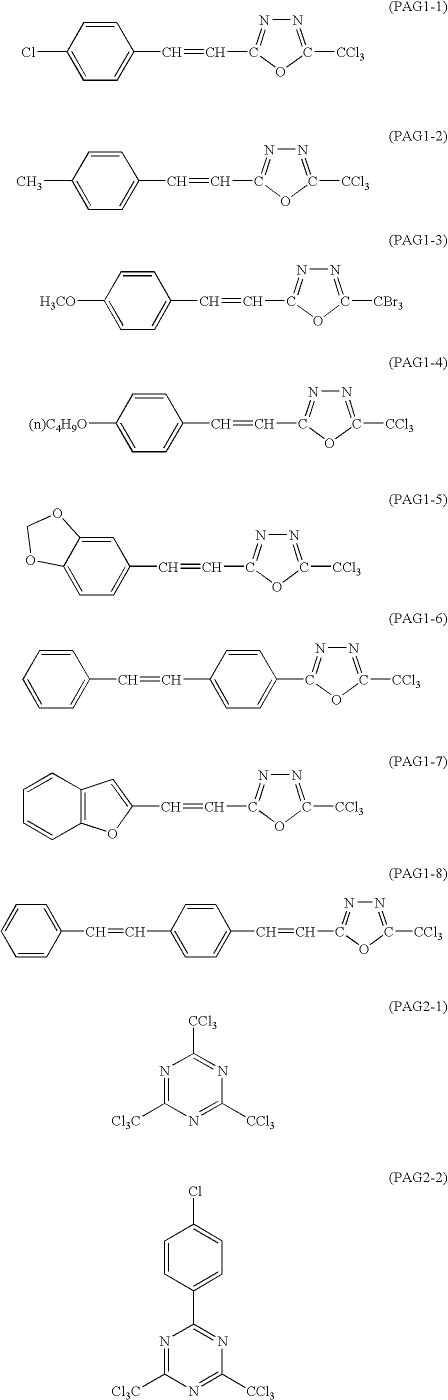

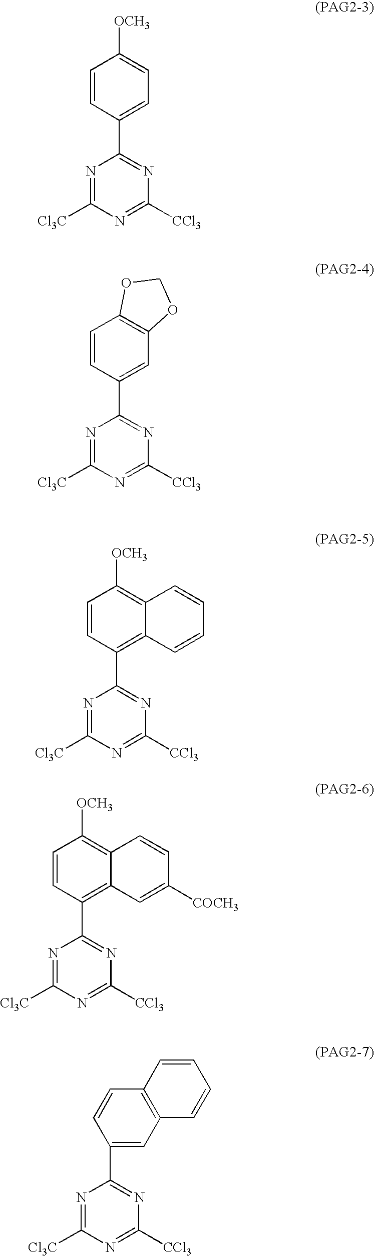

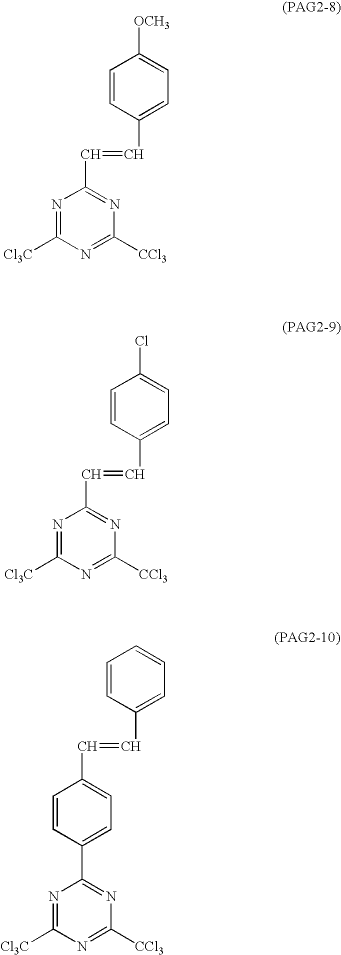

As the iodonium salts and sulfonium salts, preferably mentioned are iodonium salts of the following general formula (PAG3) and sulfonium salts of the following general formula (PAG4).

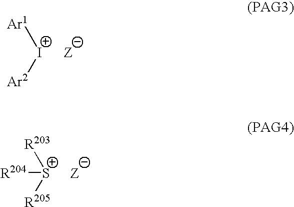

Here, Ar¹ and Ar² represent each independently a substituted or unsubstituted aryl group. R²⁰³, R²⁰⁴ and R²⁰⁵ represent each independently a substituted or unsubstituted alkyl group or aryl group.

Z⁻ represents a counter anion, and examples thereof include, but not limited to, perfluoroalkanesulfonate anions such as BF₄⁻, AsF₆⁻, PF₆⁻, SbF₆⁻, SiF₆²⁻ and ClO₄⁻, CF₃SO₃⁻; toluenesulfonate anions; substituted benzenesulfonate anions such as dodecylbenzenesulfonate anions and pentafluorobenzenesulfonate anions; condensed polynuclear aromatic sulfonate anions such as a naphthalene-1-sulfonate anion and anthraquinonesulfonate anion; sulfonic group-containing dyes.

Two of R²⁰³, R²⁰⁴ and R²⁰⁵, and Ar¹ and Ar² may be connected via a single bond or substituent. Specific examples thereof include, but not limited to, the following compounds.

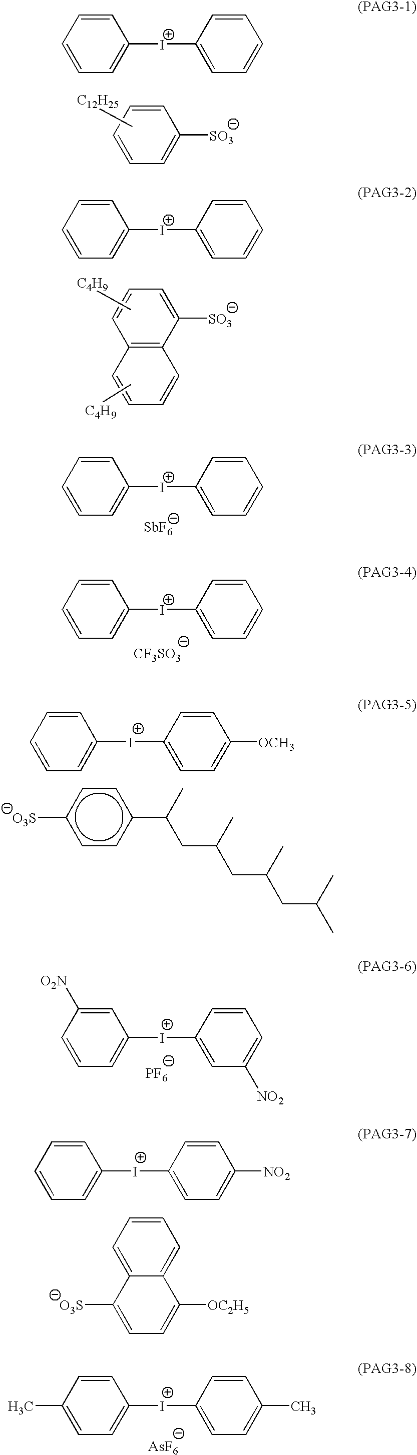

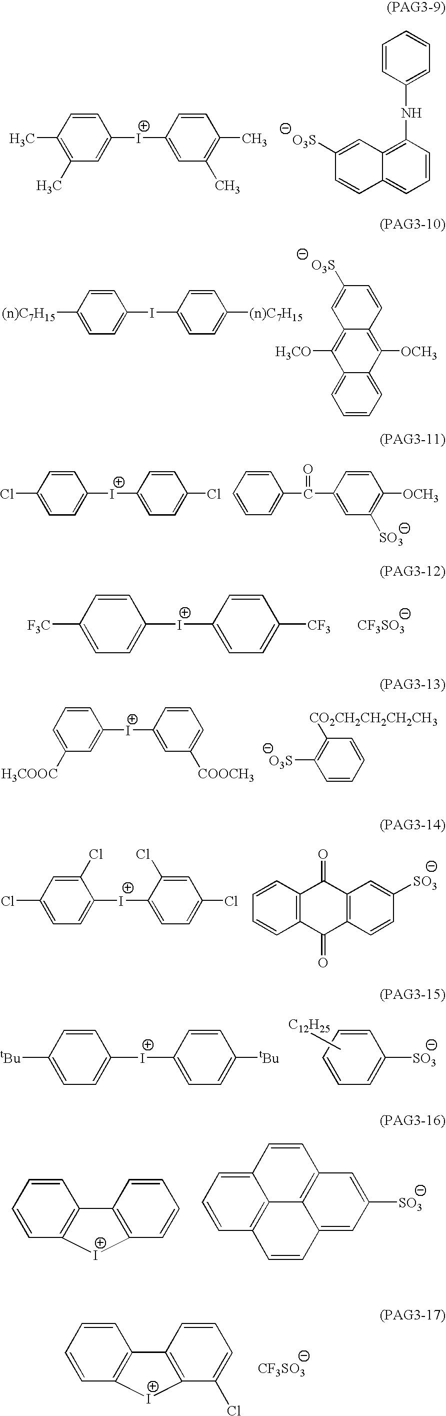

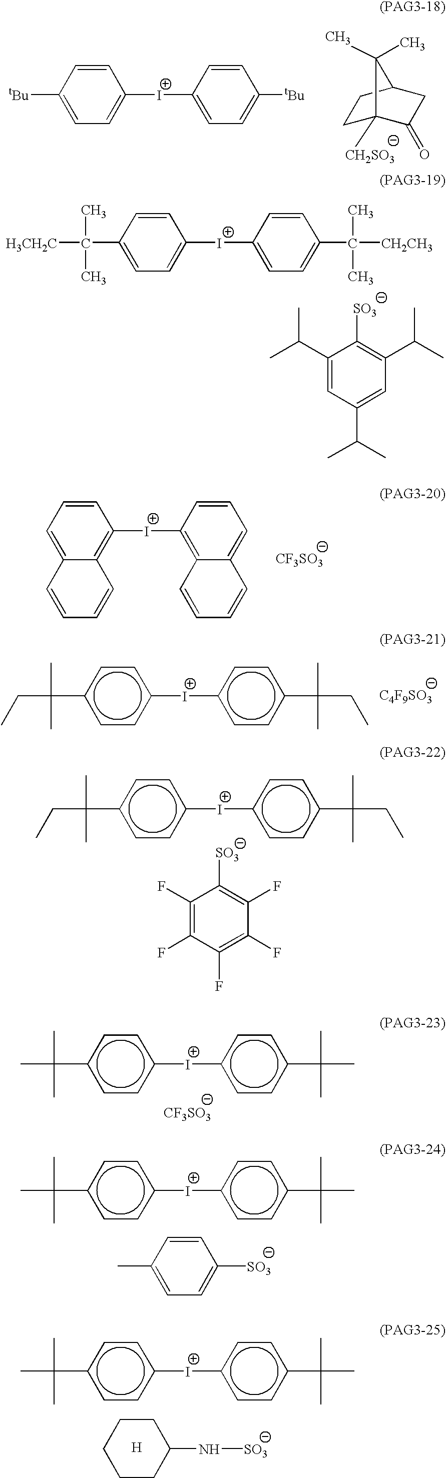

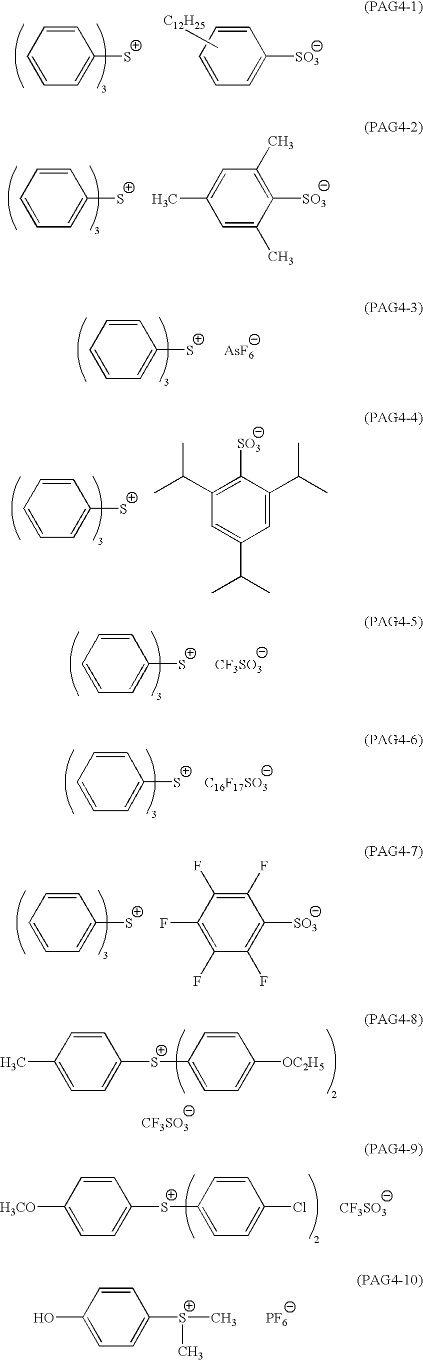

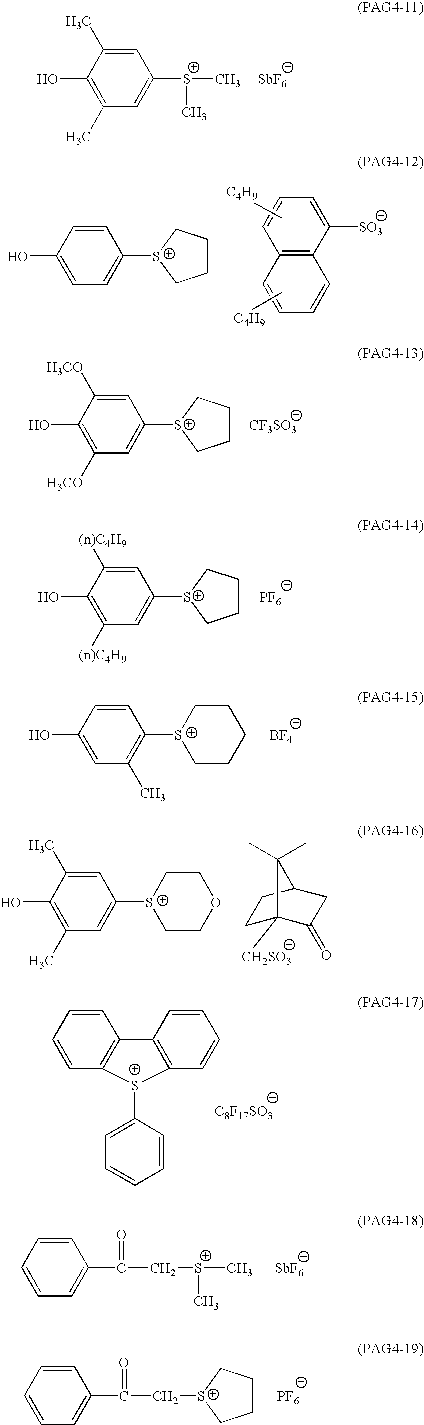

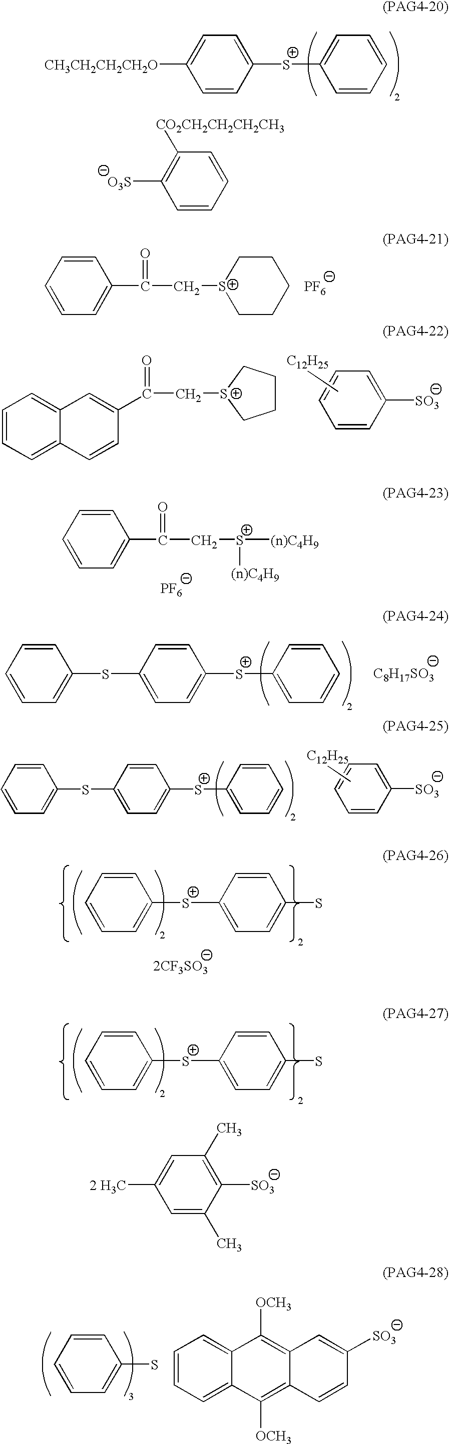

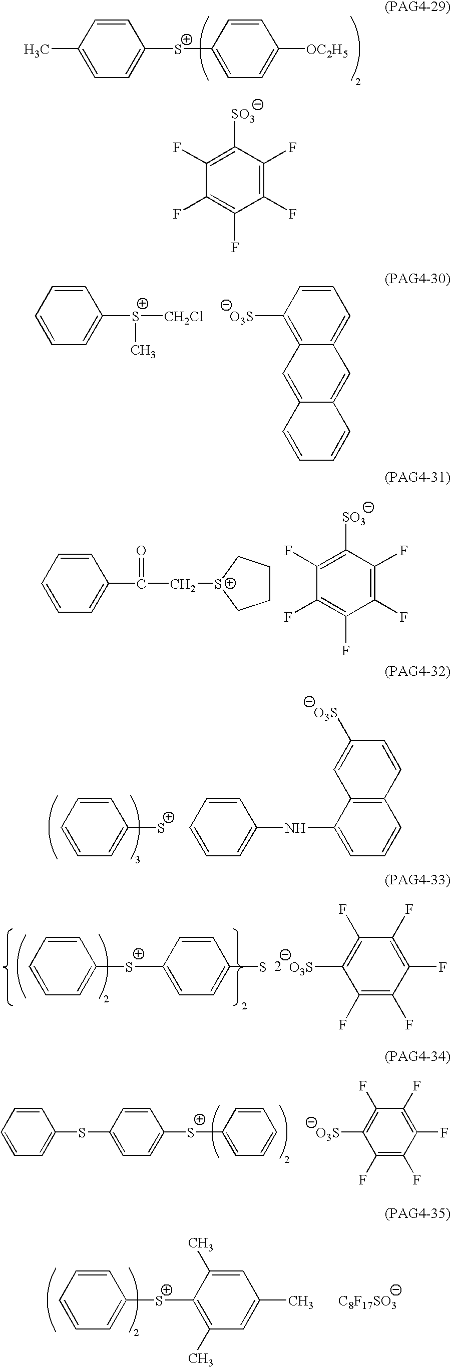

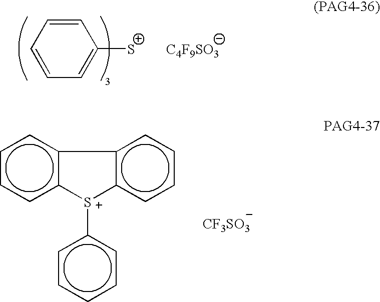

The above-described onium salts of the general formulae (PAG3) and (PAG4) are known, and can be synthesized by methods described in, for example, J. W. Knapczyketal, J. Am. Chem. Soc., 91, 145 (1969), A. L. Maycoketal, J. Org. Chem., 35, 2532 (1970), E. Goethasetal, Bull. Soc. Chem. Belg., 73, 546 (1964), H. M. Leicester, J. Ame. Chem. Soc., 51, 3587 (1929), J. V. Crivello et al., J. Plym. Chem. Ed., 18, 2677 (1980), U.S. Pat. Nos. 2,807,648 and 4,247,473 and JP-A No. 53-101,331.

As the disulfone derivative and imide sulfonate derivative, preferably mentioned are disulfone derivatives of the following general formula (PAG5) and imide sulfonate derivatives of the following general formula (PAG6).

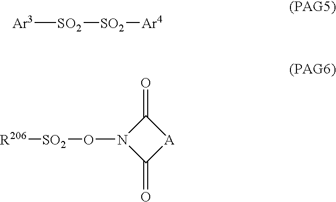

In the formulae, Ar³ and Ar⁴ represent each independently a substituted or unsubstituted aryl group. R²⁰⁶ represents a substituted or unsubstituted alkyl group or aryl group. A represents a substituted or unsubstituted alkylene group, alkenylene group or arylene group. Specific examples thereof include, but not limited to, the following compounds.

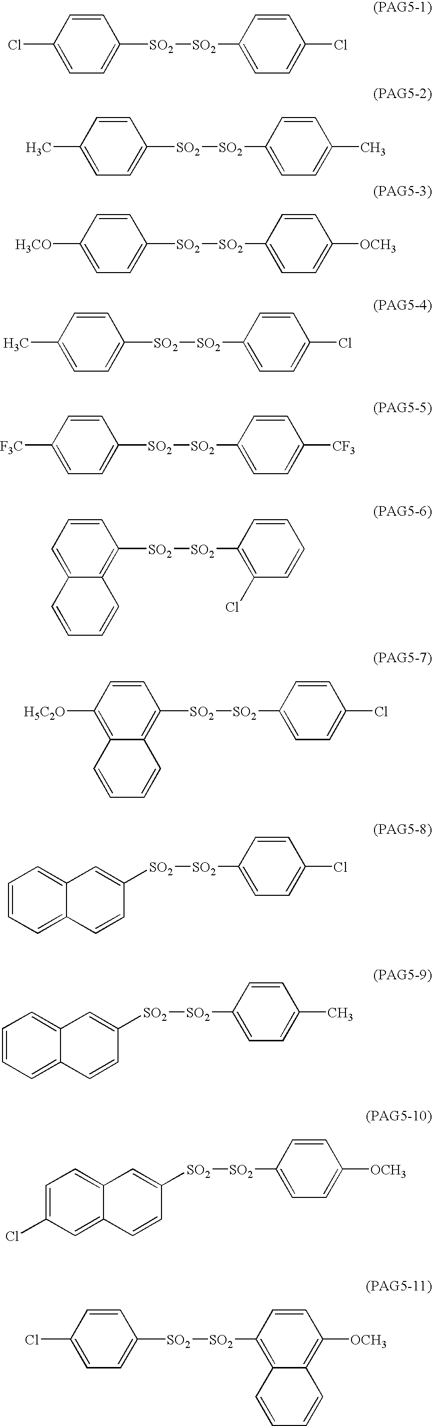

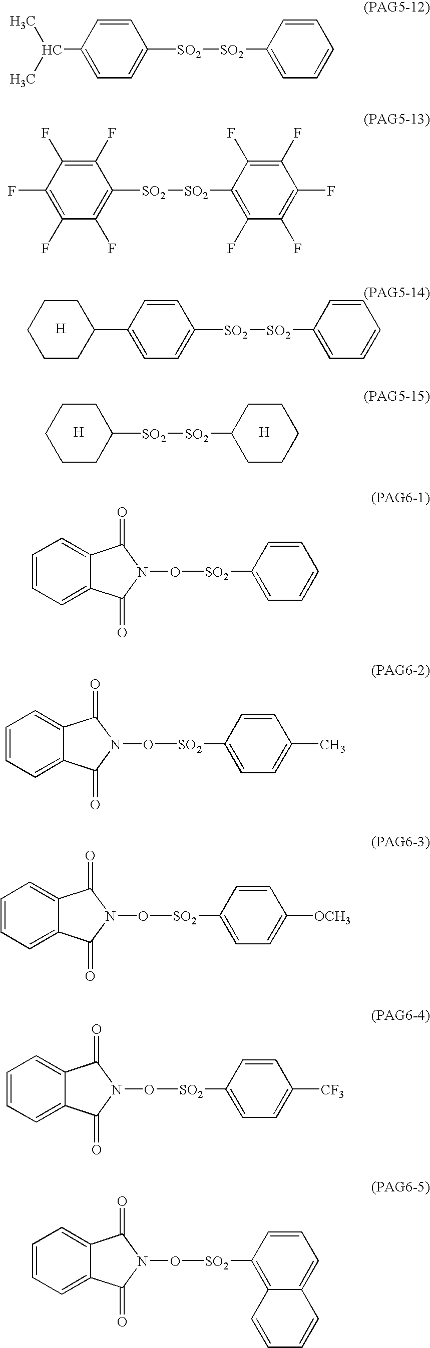

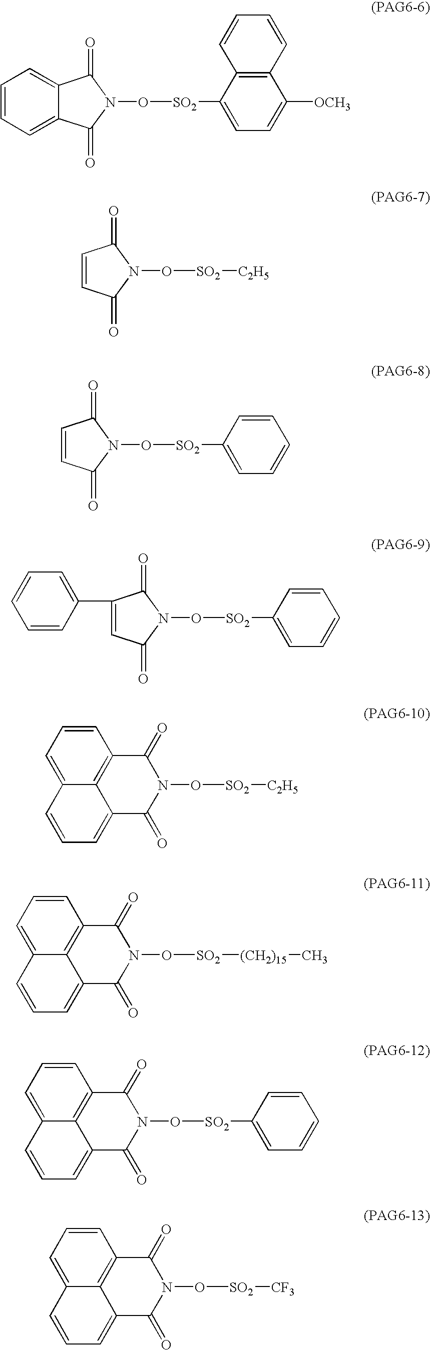

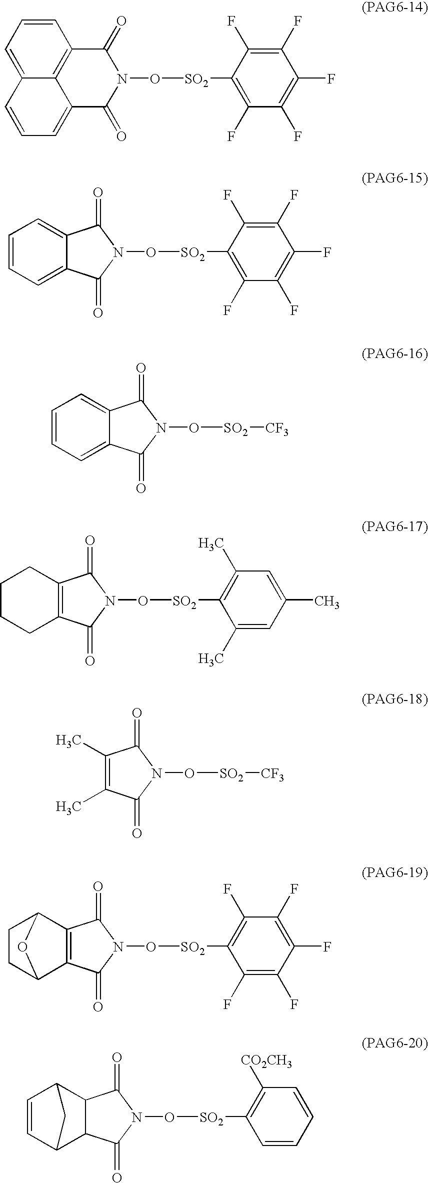

As the diazodisulfone derivative, preferably mentioned are diazodisulfone derivatives of the following general formula (PAG7).

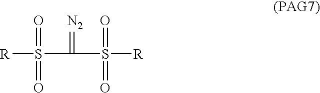

Here, R represents a linear, branched or cyclic alkyl group, or an aryl group optionally substituted. Specific examples thereof include, but not limited to, the following compounds.

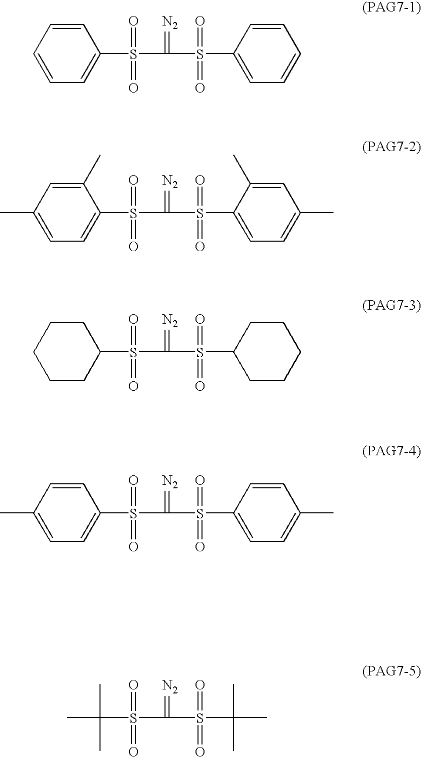

As the sulfonate derivative, further preferably mentioned are compounds of the following formula (I).

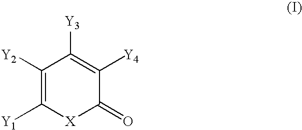

In the formula (I), Y₁ to Y₄ represent each independently a hydrogen atom, alkyl group, aryl group, halogen atom, alkoxy group or group having —OSO₂R. At least one of Y₁ to Y₄ is a group having —OSO₂R. At least two of Y₁ to Y₄ may be mutually connected to form a ring structure. R represents an alkyl group, aryl group or camphor residue. X represents —O—, —S—, —NH—, —NR₆₁— or —CHₙ(R₆₁)ₘ—. Here, R₆, represents an alkyl group, and m and n represent 0, 1 or 2, wherein, m+n=2. The alkyl group represented by Y₁ to Y₄ is preferably an alkyl group having 1 to 30 carbon atoms, and examples thereof include linear or branched alkyl groups such as a methyl group, ethyl group, propyl group, n-butyl group, sec-butyl group and t-butyl group, and cyclic alkyl groups such as a cyclopropyl group, cyclopentyl group, cyclohexyl group, adamantyl group, norbonyl group and boronyl group, and these my further have a substituent. The aryl group represented by Y₁ to Y₄ is preferably an aryl group having 6 to 14 carbon atoms, and examples thereof include a phenyl group, tolyl group and naphthyl group, and these my further have a substituent.

Examples of the halogen atom represented by Y₁ to Y₄ include a chlorine atom, bromine atom, fluorine atom and iodine atom. Examples of the alkoxy group represented by Y₁ to Y₄ include preferably alkoxy groups having 1 to 5 carbon atoms, for example, a methoxy group, ethoxy group, propoxy group and butoxy group. These my further have a substituent. At least two of Y₁ to Y₄ may be mutually connected to form a ring structure, however, it is preferable that adjacent two groups form an aromatic ring. This ring may contain a hetero atom or oxo group. It may be further substituted. The group having —OSO₂R represented by Y₁ to Y₄ means a group represented by —OSO₂R itself or, an organic group having a group represented by —OSO₂R as a substituent. Examples of the organic group having —OSO₂R as a substituent include those groups containing —OSO₂R substituted on alkyl groups, aryl groups and alkoxy groups as Y₁ to Y₄.

The alkyl group represented by R is preferably an alkyl group having 1 to 30 carbon atoms, and examples thereof include linear or branched alkyl groups such as a methyl group, ethyl group, propyl group, n-butyl group, sec-butyl group and t-butyl group, and cyclic alkyl groups such as a cyclopropyl group, cyclopentyl group, cyclohexyl group, adamantyl group, norbonyl group and boronyl group, and these my further have a substituent. The aryl group represented by R is preferably an aryl group having 6 to 14 carbon atoms, and examples thereof include a phenyl group, tolyl group and naphthyl group, and these my further have a substituent.

X represents —O—, —S—, —NH—, —NR₆₁— or —CHₙ(R₆₁)ₘ—. Here, R₆₁ represents an alkyl group, and m and n represent 0, 1 or 2, wherein, m+n=2. R₆₁ is preferably an alkyl group having 1 to 30 carbon atoms, and examples thereof include linear or branched alkyl groups such as a methyl group, ethyl group, propyl group, n-butyl group, sec-butyl group and t-butyl group, and cyclic alkyl groups such as a cyclopropyl group, cyclopentyl group, cyclohexyl group, adamantyl group, norbonyl group and boronyl group, and these my further have a substituent.

Y₁ and Y₂ are preferably mutually connected to form a structure of the following formula (II).

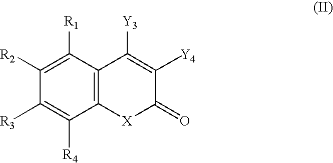

In the above-described formula (II), X represents —O—, —S—, —NH—, —NR₆₁— or —CHₙ(R₆₁)ₘ—. Y₃ and Y₄ represent each independently a hydrogen atom, alkyl group, aryl group, halogen atom, alkoxy group or group having —OSO₂R. Here, R represents an alkyl group, aryl group or camphor residue. R₆₁ represents an alkyl group, and m and n represent 0, 1 or 2, wherein, m+n=2. R₁ to R₄ represent each independently a hydrogen atom, alkyl group, alkoxy group, halogen atom, hydroxyl group, nitro group, cyano group, aryl group, aryloxy group, alkoxycarbonyl group, acyl group, acyloxy group or group having —OSO₂R.

At least one of R₁ to R₄, Y₃ and Y₄ is a group having —OSO₂R.

Y₃ is preferably a group having —OSO₂R.

Therefore, among compounds of the above-described formula (I), compounds of the following formula (III) are further preferable, and compounds of the following formula (IV) are more preferable.

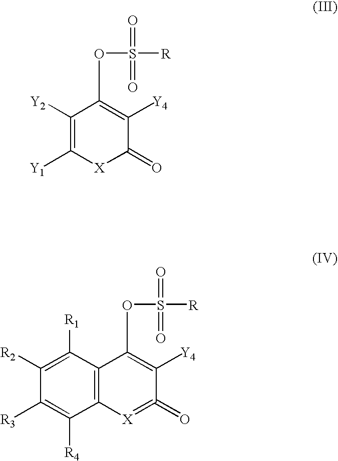

In the formulae (III) and (IV), definitions of Y₁, Y₂, Y₄, R and X are the same as in the formulae (I) and (II). R₁ to R₄ represent a hydrogen atom, alkyl group, alkoxy group, halogen atom, hydroxyl group, nitro group, cyano group, aryl group, aryloxy group, alkoxycarbonyl group, acyl group, acyloxy group or group having —OSO₂R. The alkyl group represented by R₁ to R₄ is preferably an alkyl group having 1 to 30 carbon atoms, and examples thereof include linear or branched alkyl groups such as a methyl group, ethyl group, propyl group, n-butyl group, sec-butyl group and t-butyl group, and cyclic alkyl groups such as a cyclopropyl group, cyclopentyl group, cyclohexyl group, adamantyl group, norbonyl group and boronyl group, and these my further have a substituent. The aryl group represented by R₁ to R₄ is preferably an aryl group having 6 to 14 carbon atoms, and examples thereof include a phenyl group, tolyl group and naphthyl group, and these my further have a substituent.

Examples of the halogen atom represented by R₁ to R₄ include a chlorine atom, bromine atom, fluorine atom and iodine atom. Examples of the alkoxy group represented by R₁ to R₄ include preferably alkoxy groups having 1 to 5 carbon atoms, for example, a methoxy group, ethoxy group, propoxy group and butoxy group. These my further have a substituent.

The group having —OSO₂R represented by R₁ to R₄ means a group represented by —OSO₂R itself or, an organic group having a group represented by —OSO₂R as a substituent. Examples of the organic group having —OSO₂R as a substituent include those groups containing —OSO₂R substituted on alkyl groups, alkoxy groups, hydroxyl group, nitro group, cyano group, aryl groups, aryloxy groups, alkoxycarbonyl groups, acyl group or acyloxy groups as R₁ to R₄. At least two of R₁ to R₄ may be mutually connected to form a ring structure.

When Y₁ to Y₄, R, X and R₁ to R₄ further have a substituent, substituents such as, for example, aryl groups (e.g., phenyl group), nitro group, halogen atoms, carboxyl group, hydroxyl group, amino group, cyano group and alkoxy groups (preferably having 1 to 5 carbon atoms) are mentioned. Regarding the aryl group and arylene group, alkyl groups (preferably having 1 to 5 carbon atoms) are further mentioned.

Preferable specific examples of the compound of the formula (1) are shown below, but the present invention is not limited to them.

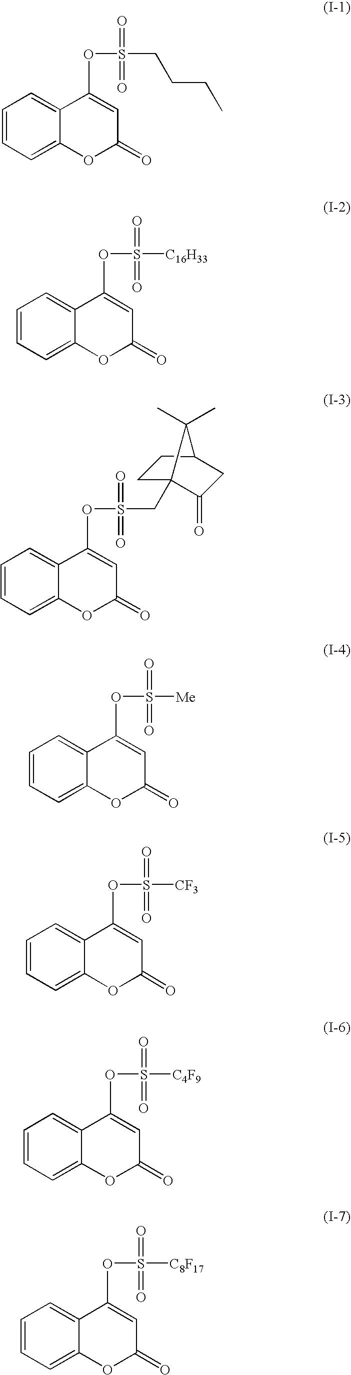

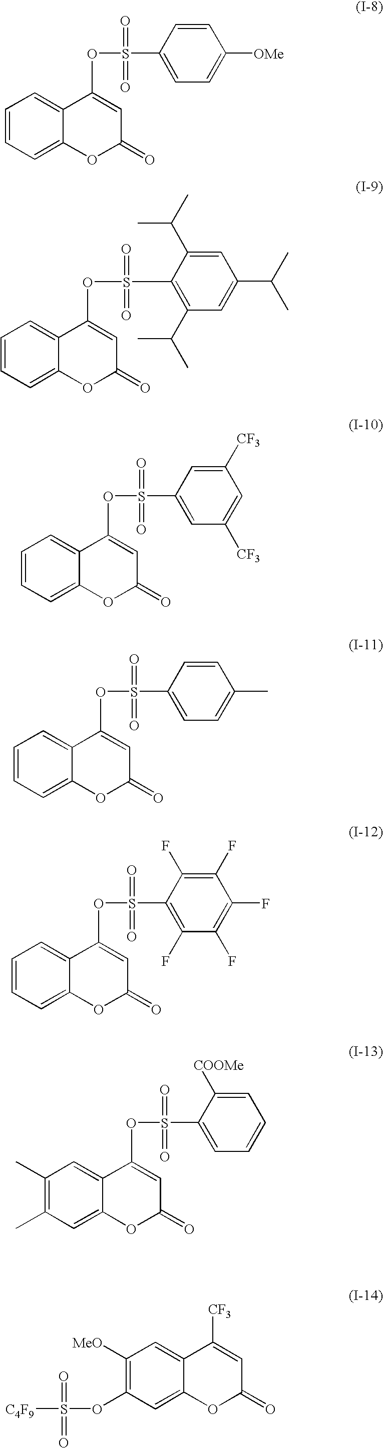

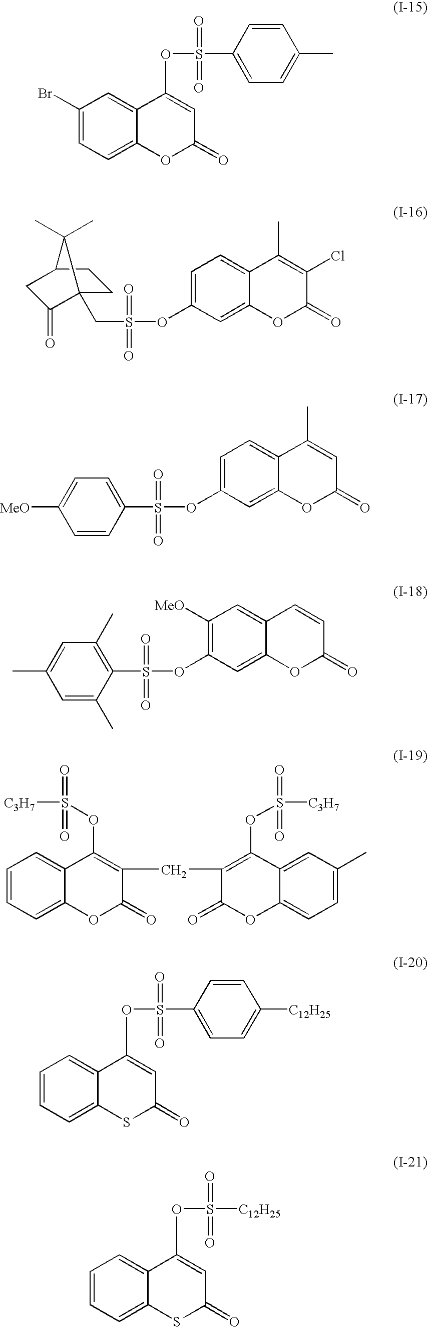

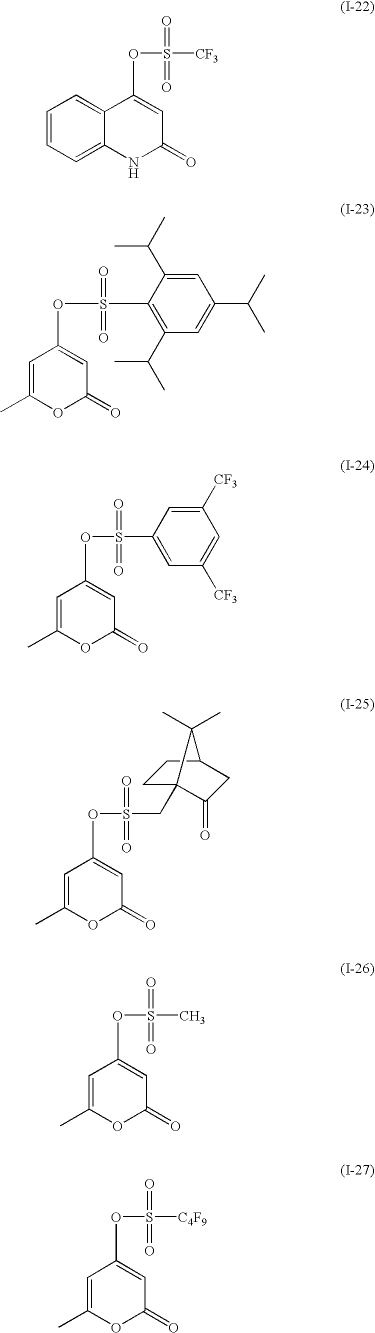

Optical acid generators represented by the formula (I) can be used singly or in combination of two or more.

Further, as the optical acid generator, particularly preferable are bis(4-t-butylphenyl)iodonium p-toluenesulfonate, 4-methoxyphenyl-phenyliodonium camphorsulfonate, bis(4-t-butylphenyl)iodonium camphorsulfonate, diphenyliodonium p-toluenesulfonate, bis(4-t-butylphenyl)iodonium perfluorobutylsulfonate, bis(4-t-butylphenyl)iodonium cyclohexylsulfamate, succinimidyl p-toluenesulfonate, naphthalimidyl camphorsulfonate, 2-[(tribromomethyl)sulfonyl]pyridine and tribromomethyl phenylsulfone. These can be used singly or, if necessary, in combination of two or more.

The content of a thermal acid generator as the component (C) in the positive resist composition of the present invention is preferably 0.5 to 20 wt %, more preferably 1 to 15 wt % based on the total amount of the components (A), (B) and (C).

Also the kind of the thermal acid generator and its compounding amount themselves or, in combination with the components (A) and (C), are so selected that a property for producing a desired stamper is obtained, and so set as to obtain desired sensitivity and resolution at the strength of an active energy ray such as laser light used for exposure. Further, the compounding amount is preferably so set that a baking treatment is unnecessary in forming a coat or layer irrespective of wavelength range to be used.

The positive resist composition can further contain an acid added previously. By addition of this acid in suitable amount, properties such as photosensitivity can be improved by a synergistic action with a thermal acid generator, and resolution, sensitivity and the like can be further improved. As the acid which can be used for this purpose, mentioned are inorganic acids such as hydrochloric acid, nitric acid, sulfuric acid and phosphoric acid, and organic acids such as carboxylic acids such as acetic acid, oxalic acid, tartaric acid and benzoic acid, sulfonic acid, sulfinic acid, phenols, imides, oximes and aromatic sulfoneamides, and one or more acids selected from them can be added according to the purpose. Of them, p-toluenesulfonic acid is particularly preferable. The acid can be used in an amount of preferably 0.001 to 1 mol, more preferably 0.05 to 0.5 mol based on 1 mol of a thermal acid generator.

Further, to the positive resist composition, one or more compounds selected from close adherence improvers, metal chelate inhibitors, surface adjusting agents and the like can be added according to the purposed application, in addition to the above-described components. Further, a UV absorber may also be added to prevent decomposition of an acid generator in a bright room.

The positive resist composition may also be prepared as a liquid composition by addition of a solvent. Examples of the solvent include water, hydrocarbon solvents such as hexane, toluene and xylene, ether solvents such as dioxane, tetrahydrofuran, ketone solvents such as acetone, methyl ethyl ketone and methyl isobutyl ketone, acetate solvents such as ethyl acetate and propylene glycol methyl ether acetate, and according to the application of the positive resist composition, these solvents can be used singly or in combination of two or more. For film formation by application, for example, the solvent can be used in such an amount that the solid content is preferably about 1 to 50 wt %, more preferably about 2 to 20 wt %. Depending on the kind of the solvent, a component for maintaining liquid state may be added. For example, required components are allowed to be contained in water or solvent mainly composed of water to give a liquid composition in the form of emulsion, using an emulsifier.

On the other hand, a liquid composition obtained by using a solvent if necessary can also be formed on a base plate to give a dry film.

A positive resist composition is prepared in the form of liquid using the solvent as described above, the resultant liquid composition is applied on a base plate to form a film, and positions according to a given pattern are irradiated with an active energy ray such as laser light having a wavelength necessary for patterning and further, subjected to a development treatment, thus, a given resist pattern can be obtained. In this procedure, by adjusting the formulation of the positive resist composition, a baking treatment by heating (prebake) in film formation can be made unnecessary. By thus omitting a baking treatment, it is also possible to improve efficiency of production of a master for producing a stamper having a film or layer of the positive resist composition. Also with respect to baking after exposure (post bake), it can be selected whether to carry out post bake or not according to the formulation of the positive resist composition.

As the base plate for film formation of a positive resist composition, base plates for production of a stamper made of a material such as glass and metal can be used. On the base plate, a surface treatment for further improving close adherence of a positive resist composition to the base plate may be carried out, if necessary. As such a surface treatment, treatment with a silane coupling agent is mentioned as a suitable example.

The method of forming a photosensitive layer using a positive resist composition on a base plate includes a method in which a liquid composition is prepared, and applied in given amount on a base plate so that desired film thickness after drying is obtained, and a solvent is evaporated to obtain a photosensitive layer, a method in which a composition is applied on a base plate for dry film formation to give a dry film which is then laminated on a base plate on which a photosensitive layer is to be formed. For application on a base plate, a spin coat method, blade coat method, spray coat method, wire bar coat method, dipping method, air knife coat method, roller coat method, curtain coat method and the like can be used. The thickness of a photosensitive layer is set according to its purposed application, and can be selected, for example, in the range of 0.05 to 1 μm. The thickness of a photosensitive layer is set according to properties required for a master for producing a stamper, and can be selected, for example, in the range of 0.1 to 0.3 μm.

Exposure of a photosensitive layer provided on a base plate can be carried out by an exposure apparatus which can irradiate an active energy ray containing a photosensitive wavelength. For exposure of a photosensitive layer in the form of pattern, usual exposure methods can be used such as, for example, methods in which exposure is performed via a mask having optically transparent parts corresponding to a desired pattern, given parts of a photosensitive layer on a base plate are directly irradiated with an active energy ray, and the like. In the case of use of a laser apparatus, both apparatuses of pulse irradiation mode and apparatuses of continuous irradiation mode are permissible.

In the case of use of an array type light source such as a light emitting diode array and in the case of exposure control with an optical shutter material such as liquid crystal and PLZT of a light source such as halogen lamps, metal halide lamps and tungsten lamps, digital exposure according to image signals is possible, and in this case, direct writing can be carried out without using a mask material. In this method, however, an optical shutter material is newly necessary in addition to a light source, thus, it is preferable to use laser as a light source in the case of digital exposure.

When laser light is used as a light source, it is possible to squeeze light in the form of beam and carry out latent image recording by scanning exposure according to image data, and further when laser is used as a light source, it is easy to squeeze exposure area into fine size and image recording of high resolution is made possible.

In the case of use of a laser apparatus for exposure, the wavelength of laser light to be irradiated is not particularly restricted, and laser apparatuses irradiating laser light of a wavelength of 266 nm, 351 nm, 355 nm, 375 nm, 405 nm, 436 nm, 650 nm, 610 nm, 760 nm or 830 nm can be used. As the laser light source used in the present invention, solid lasers such as ruby laser, YAG laser and glass laser; gas lasers such as He—Ne laser, Ar ion laser, Kr ion laser, CO₂ laser, CO laser, He—Cd laser, N₂ laser and excimer laser; semiconductor lasers such as InGaP laser, AlGaAs laser, GaAsP laser, InGaAs laser, InAsP laser, CdSnP₂ laser and GaSb laser; chemical laser and coloring matter laser, which are generally well known are mentioned. The laser apparatus is not particularly restricted, and a semiconductor laser which can be manufactured in small size is useful. The output of an irradiation apparatus at which desired sensitivity based on the formulation and thickness of a photosensitive layer, for example, effective resolution by treatment in a bright room is obtained is used, and high output lasers of up to about 20 W can also be used.

The light intensity of a light source for irradiation can be 1.0×10² mJ/s·cm² or more, preferably 1.0×10³ mJ/s·cm² or more.

As the developer for removing an exposed portion from on a base plate after exposure, alkali developers which can dissolve a portion obtained by action of an acid on a constitutional unit having a polymerizable ethylenically unsaturated bond and an alkali-soluble group can be used. Examples of alkali components used in the developer include inorganic alkali salts such as sodium silicate, potassium silicate, lithium silicate, ammonium silicate, sodium metasilicate, potassium metasilicate, sodium hydroxide, potassium hydroxide, lithium hydroxide, sodium carbonate, sodium bicarbonate, potassium carbonate, dibasic sodium phosphate, tribasic sodium phosphate, dibasic ammonium phosphate, tribasic ammonium phosphate, sodium borate, potassium borate and ammonium borate; and organic amine compounds such as monomethylamine, dimethylamine, trimethylamine, monoethylamine, diethylamine, triethylamine, monoisopropylamine, diisopropylamine, monobutylamine, monoethanolamine, diethanolamine, triethanolamine, monoisopropanolamine and diisopropanolamine. Of them, silicates of alkali metals such as sodium metasilicate are preferable. To the developer, various surfactants (anionic surfactants, nonionic surfactants, ampholytic surfactants) and organic solvents such as alcohols can be added, if necessary. The content of the alkali components can be selected depending on the formulation of a positive resist composition and the like, and for example, can be about 0.1 to 5 wt %.

### EXAMPLES

### Reference Example of Method for Producing Polymer (1) and Raw Materials thereof

The weight average molecular weight (Mw) of a polymer in Reference Example was measured by gel permeation chromatography under the following conditions.

Column: TSKgel Super HM-M (two) and HM-H (one) [all manufactured by Tosoh Corp.] were connected serially.

Column maintained temperature: 40° C.

Detector: RI

Developing solvent: tetrahydrofuran (flow rate: 0.5 ml/min.)

Standard substance: polystyrene

### Reference Example 1

### Synthesis of Monomer

To 50 g of methacrylic acid was added 42 g of ethyl vinyl ether and 0.4 g of phosphoric acid, and these are reacted at room temperature for 3 hours. The conversion rate of methacrylic acid was 82% and, selection rate to 1-ethoxyethyl methacrylate was 85%. The reaction solution was neutralized with a 5% sodium carbonate aqueous solution, then, an organic layer obtained by liquid partitioning was concentrated under reduced pressure, to obtain 74 g of 1-ethoxyethyl methacrylate.

¹H-NMR spectrum of the intended compound is described below.

¹H-NMR spectrum (400 MHz)

Measurement apparatus: GSX-400 manufactured by JEOL

Measuring solvent: Heavy chloroform

δ: 6.16-6.14 (m, 1H), 6.00 (q, J=5.4 Hz, 1H), 5.60-5.59 (m, 1H), 3.73 (dq, J=9.5, 7.1 Hz, 1H), 3.56 (dq, J=9.6, 7.1 Hz, 1H), 1.95-1.94 (m, 3H), 1.44 (d, J=5.1 Hz, 3H), 1.22 (t, J=7.1 Hz, 3H)

### Reference Example 2

### Production of Vinyl Polymer (Q-1)

Into a flask equipped with a dropping device, stirring device, thermometer, cooling tube and nitrogen gas introducing tube was charged 200.0 g of cyclohexanone and this was heated up to 80° C., and a uniform solution of 40 g of 1-ethoxyethyl methacrylate, 160 g of butyl methacrylate and 16 g of 2,2′-azobis-2-methylbutyronitrile (AMBN) was dropped over a period of 2 hours from a dropping apparatus while stirring under a nitrogen atmosphere. After completion of dropping, a mixed solution of AMBN/propylene glycol monomethyl ether acetate=0.2 g/1.8 g was added every 30 minutes three time, and the resulting mixture was aged at 80° C. for 3.5 hours, to terminate the polymerization reaction. The resultant polymer solution had a solid content of 53 wt %, and a vinyl polymer (Q-1) having a weight average molecular weight of 13,000 was obtained.

### Example 1

100 parts by weight of the vinyl polymer (Q-1), 20 parts by weight of a cyanine coloring matter shown below, 10 parts by weight of a thermal acid generator shown below and 0.5 parts by weight of p-toluenesulfonic acid were added into methyl ethyl ketone so that the solid content was 3 wt %, obtaining a liquid composition.

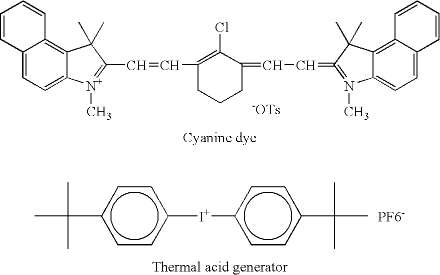

This liquid composition was applied on a glass base plate so that the dry film thickness was 0.1 μm, and dried at room temperature to form a photosensitive layer. This photosensitive layer was irradiated with laser under the following conditions.

Resolution: 6400 dpi

Laser output (total): 5 W

Laser wavelength for drawing: 830 nm

Laser scanning speed: 6000 mm/sec.

After exposure, the photosensitive layer was developed with a 1.5 wt % Na₂CO₃ aqueous solution (25° C., 1 minute), and washed and dried, then, the resultant resist pattern was evaluated. As a result, resolution of 0.8 μm Line/Space was confirmed to be possible.

### Example 2

100 parts by weight of the vinyl polymer (Q-1), 20 parts by weight of a cyanine coloring matter shown below and 10 parts by weight of a thermal acid generator shown below were added into methyl ethyl ketone so that the solid content was 3 wt %, obtaining a liquid composition.

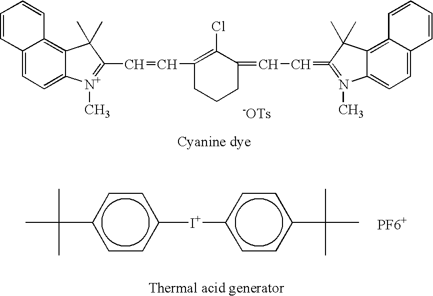

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Example 3

100 parts by weight of the vinyl polymer (Q-1), 20 parts by weight of a cyanine coloring matter shown below and 10 parts by weight of a thermal acid generator shown below were added into methyl ethyl ketone so that the solid content was 3 wt %, obtaining a liquid composition.

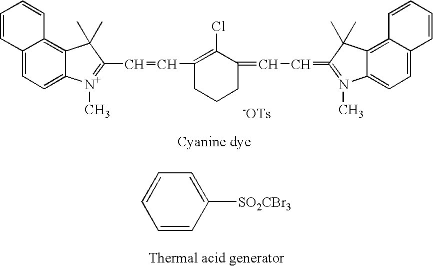

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Example 4

100 parts by weight of the vinyl polymer (Q-1), 20 parts by weight of a cyanine coloring matter shown below and 10 parts by weight of a thermal acid generator shown below were added into methyl ethyl ketone so that the solid content was 3 wt %, obtaining a liquid composition.

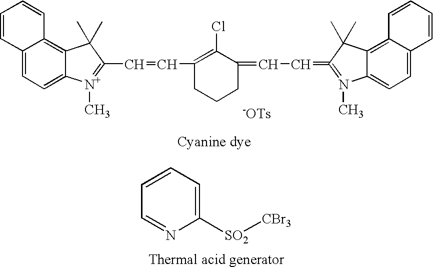

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Example 5

100 parts by weight of the vinyl polymer (Q-1), 20 parts by weight of a cyanine coloring matter shown below, 10 parts by weight of a thermal acid generator shown below and 0.5 parts by weight of p-toluenesulfonic acid were added into methyl ethyl ketone so that the solid content was 3 wt %, obtaining a liquid composition.

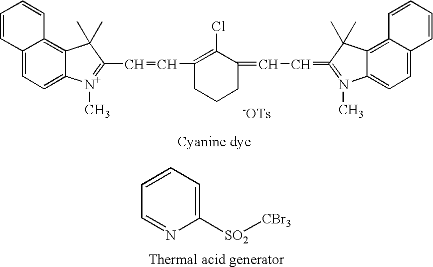

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Example 6

100 parts by weight of the vinyl polymer (Q-1), 20 parts by weight of a cyanine coloring matter shown below, 10 parts by weight of a thermal acid generator shown below and 0.5 parts by weight of p-toluenesulfonic acid were added into methyl ethyl ketone so that the solid content was 3 wt %, obtaining a liquid composition.

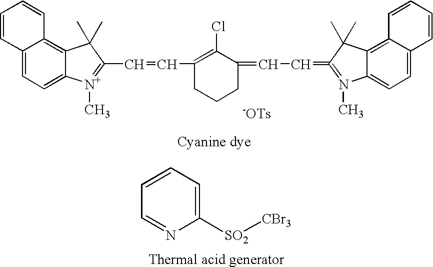

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Example 7

100 parts by weight of the vinyl polymer (Q-1), 20 parts by weight of a cyanine coloring matter shown below and 10 parts by weight of a thermal acid generator shown below were added into methyl ethyl ketone so that the solid content was 3 wt %, obtaining a liquid composition.

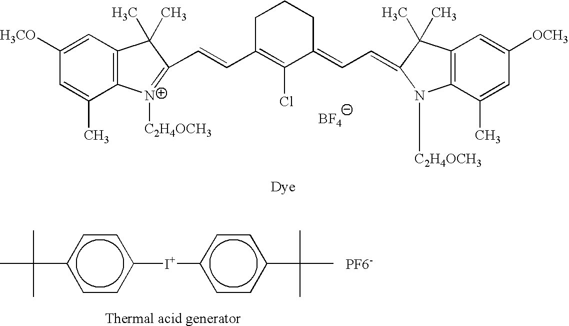

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Example 8

100 parts by weight of the vinyl polymer (Q-1), 20 parts by weight of a cyanine coloring matter shown below and 10 parts by weight of a thermal acid generator shown below were added into methyl ethyl ketone so that the solid content was 3 wt %, obtaining a liquid composition.

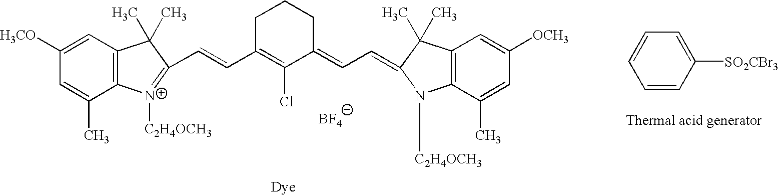

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Example 9

100 parts by weight of the vinyl polymer (Q-1), 20 parts by weight of a cyanine coloring matter shown below and 10 parts by weight of a thermal acid generator shown below were added into methyl ethyl ketone so that the solid content was 3 wt %, obtaining a liquid composition.

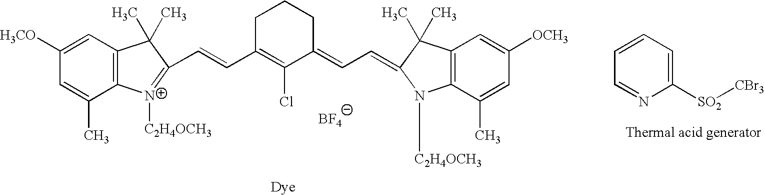

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Example 10

100 parts by weight of the vinyl polymer (Q-1), 20 parts by weight of a cyanine coloring matter shown below, 10 parts by weight of a thermal acid generator shown below and 0.5 parts by weight of p-toluenesulfonic acid were added into methyl ethyl ketone so that the solid content was 3 wt %, obtaining a liquid composition.

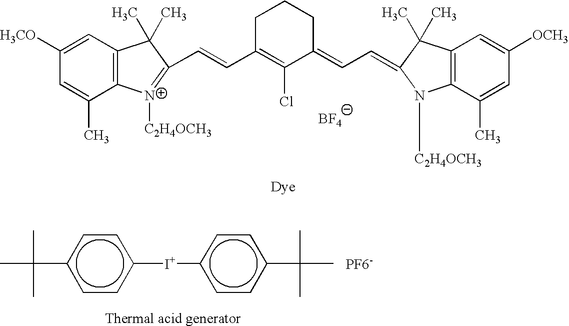

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Example 11

100 parts by weight of the vinyl polymer (Q-1), 20 parts by weight of a cyanine coloring matter shown below, 10 parts by weight of a thermal acid generator shown below and 0.5 parts by weight of p-toluenesulfonic acid were added into methyl ethyl ketone so that the solid content was 3 wt %, obtaining a liquid composition.

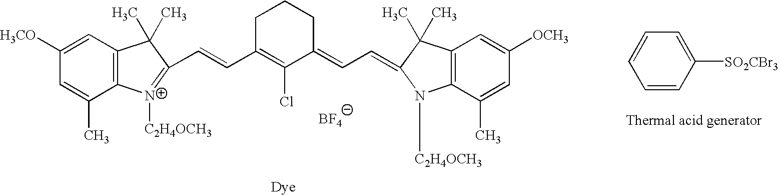

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Example 12

100 parts by weight of the vinyl polymer (Q-1), 20 parts by weight of a cyanine coloring matter shown below, 10 parts by weight of a thermal acid generator shown below and 0.5 parts by weight of p-toluenesulfonic acid were added into methyl ethyl ketone so that the solid content was 3 wt %, obtaining a liquid composition.

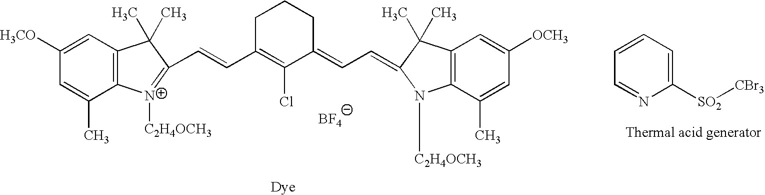

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Example 13

100 parts by weight of the vinyl polymer (Q-1), 20 parts by weight of a cyanine coloring matter shown below, 10 parts by weight of a thermal acid generator shown below, 0.5 parts by weight of p-toluenesulfonic acid and 1.5 parts by weight of a UV absorber were added into methyl ethyl ketone so that the solid content was 3 wt %, obtaining a liquid composition.

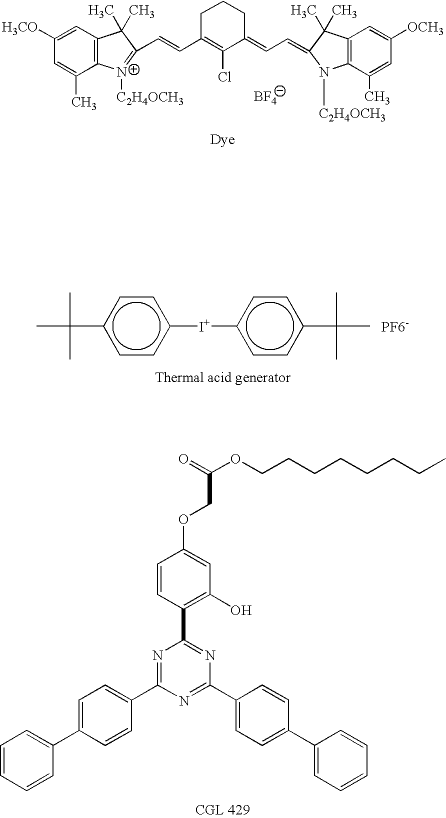

This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and the resultant resist pattern was evaluated. As a result, resolution of 0.8 μm Line/Space was confirmed to be possible.

### Examples 14 to 26

Resist patters were formed in the same manner as described above excepting that the liquid compositions (positive resist compositions) of Examples 1 to 13 were used and the laser wavelength was changed from 830 nm to 405 nm, and evaluated. As a result, resolution of 0.2 μm Line/Space was confirmed to be possible.

### Examples 27 to 39

Resist patters were formed in the same manner as described above excepting that the liquid compositions (positive resist compositions) of Examples 1 to 13 were used and the laser wavelength was changed from 830 nm to 375 nm, and evaluated. As a result, resolution of 0.1 μm Line/Space was confirmed to be possible.

### Examples 40 to 45

Liquid compositions were prepared in the same manner as in Examples 1 to 6 excepting that a coumarin coloring matter (NKX-1619, manufactured by Hayashibara Biochemical Laboratories, Inc.) was used instead of the cyanine coloring matters in Examples 1 to 6. This liquid composition was applied on a glass base plate so that the dry film thickness was 0.1 μm, and dried at room temperature to form a photosensitive layer. This photosensitive layer was subjected to laser irradiation, development and washing and drying under the same conditions as in Example 1, and each of the resultant resist patterns was evaluated. As a result, resolution of 0.8 μm Line/Space was confirmed to be possible.

1. A positive resist composition for recording medium master, comprising a vinyl polymer which has a monomer unit having an alkali-soluble group blocked by an alkyl vinyl ether.

2. The positive resist composition for recording medium master according to claim 1, further comprising a photothermal converting substance generating heat by an active energy ray and a thermal acid generator generating an acid by heat.

3. The positive resist composition for recording medium master according to claim 1, wherein said alkali-soluble group is a carboxyl group.

4. The positive resist composition for recording medium master according to claim 3, wherein said vinyl polymer is a vinyl polymer having a structural unit of the following general formula (1): 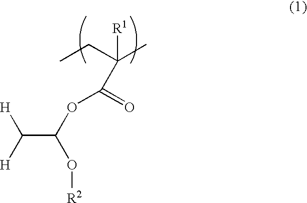
wherein, R¹ represents a hydrogen atom or lower alkyl group, and R² represents a substituted or un-substituted alkyl group.

5. The positive resist composition for recording medium master according to claim 4, wherein the vinyl polymer having a structural unit of the general formula (1) has a weight average molecular weight of 2,000 to 300,000.

6. The positive resist composition for recording medium master according to any one of claims 1 to 5, wherein said vinyl polymer is obtained from at least a monomer having an alkali-soluble group blocked by an alkyl vinyl ether.

7. The positive resist composition for recording medium master according to any one of claims 1 to 6, further comprising an acid.

8. A method of producing a recording medium master comprising:
a step of forming a layer of a positive resist composition on a base plate,
a step of irradiating a given portion of the layer with an active energy ray, and
a step of removing the irradiated portion from said base plate by alkali development to form a pattern of said positive resist composition according to information signals on the base plate,
wherein said positive resist composition contains a vinyl polymer which has a monomer unit having an alkali-soluble group blocked by an alkyl vinyl ether.

9. The method of producing a recording medium master according to claim 1, wherein the positive resist composition further comprises a photothermal converting substance generating heat by an active energy ray and a thermal acid generator generating an acid by heat.

10. The method of producing a recording medium master according to claim 9, wherein said active energy ray contains at least any of the maximum absorption wavelength±10 nm of said photothermal converting substance, 1/n wavelength of the maximum absorption wavelength and n-fold wavelength of the maximum absorption wavelength (n represents an integer of 1 or more).

11. The method of producing a recording medium master according to claim 10, wherein said maximum absorption wavelength is in the range of 200 to 900 nm.

12. The method of producing a recording medium master according to any one of claims 8 to 11, further comprising a step of heating said layer of a positive resist composition irradiated with an active energy ray before said development process.

13. The method of producing a recording medium master according to any one of claims 8 to 12, wherein said alkali-soluble group is a carboxyl group.

14. The method of producing a recording medium master according to claim 13, wherein said vinyl polymer is a vinyl polymer having a structural unit of the following general formula (1): 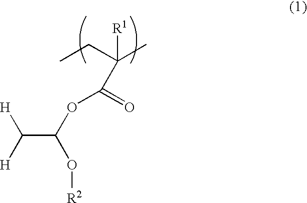
wherein, R¹ represents a hydrogen atom or lower alkyl group, and R² represents a substituted or un-substituted alkyl group.

15. The method of producing a recording medium master according to claim 14, wherein the vinyl polymer having a structural unit of the general formula (1) has a weight average molecular weight of 2,000 to 300,000.

16. The method of producing a recording medium master according to any one of claims 8 to 15, wherein said vinyl polymer is obtained from at least a monomer having an alkali-soluble group blocked by an alkyl vinyl ether.

17. The method of producing a recording medium master according to any one of claims 8 to 16, wherein the positive resist composition further comprises an acid.

18. A method of producing a stamper for recording medium comprising:
a step of forming a layer of a positive resist composition on a base plate,
a step of irradiating a given portion of the layer with an active energy ray,
a step of removing the irradiated portion from said base plate by alkali development to form a pattern of said positive resist composition according to information signals on the base plate thereby obtaining a master,
a step of forming an electrically conductive film on the surface of the master, a process of electroforming a metal on the electrically conductive film and
a step of peeling from the master a stamper made of the metal after electroformation,
wherein said positive resist composition contains a vinyl polymer which has a monomer unit having an alkali-soluble group blocked by an alkyl vinyl ether.

19. The method of producing a stamper according to claim 18, wherein the positive resist composition further comprises a photothermal converting substance generating heat by an active energy ray and a thermal acid generator generating an acid by heat.

20. The method of producing a stamper according to claim 19, wherein said active energy ray contains at least any of the maximum absorption wavelength±10 nm of said photothermal converting substance, 1/n wavelength of the maximum absorption wavelength and n-fold wavelength of the maximum absorption wavelength (n represents an integer of 1 or more).

21. The method of producing a stamper according to claim 20, wherein said maximum absorption wavelength is in the range of 200 to 900 nm.

22. The method of producing a stamper according to any one of claims 18 to 21, further comprising a step of heating said layer of a positive resist composition irradiated with an active energy ray before said development process.

23. The method of producing a stamper according to any one of claims 18 to 22, wherein said alkali-soluble group is a carboxyl group.

24. The method of producing a stamper according to claim 23, wherein said vinyl polymer is a vinyl polymer having a structural unit of the following general formula (1): 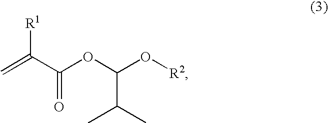
wherein, R¹ represents a hydrogen atom or lower alkyl group, and R² represents a substituted or un-substituted alkyl group.

25. The method of producing a stamper according to claim 24, wherein the vinyl polymer having a structural unit of the general formula (1) has a weight average molecular weight of 2,000 to 300,000.

26. The method of producing a stamper according to any one of claims 18 to 25, wherein said vinyl polymer is obtained from at least a monomer having an alkali-soluble group blocked by an alkyl vinyl ether.

27. The method of producing a stamper according to any one of claims 18 to 26, wherein the positive resist composition further comprises an acid.
